(19) United States
(12) Patent Application Publication
(10) Pub. No.: US 2024/0316932 A1
(43) Pub. Date: Sep. 26, 2024

(54) PIEZOELECTRIC ACTUATOR, LIQUID DISCHARGE HEAD, AND LIQUID DISCHARGE APPARATUS

(71) Applicant: Toshiaki MASUDA, Kanagawa (JP)

(72) Inventor: Toshiaki MASUDA, Kanagawa (JP)

(21) Appl. No.: 18/607,640

(22) Filed: Mar. 18, 2024

(30) Foreign Application Priority Data
Mar. 24, 2023 (JP) 2023-047663

(51) Int. Cl. B41J 2/14; H10N 30/87

(52) U.S. Cl. CPC B41J 2/14274; H10N 30/87

(57) ABSTRACT

A piezoelectric actuator includes: a substrate having a pressure chamber elongated in a first direction, the pressure chamber having one end in the first direction; a diaphragm on the substrate and having a one face facing the pressure chamber; and a piezoelectric element including: a lower electrode; a piezoelectric body; and an upper electrode, sequentially laminated on another face of the diaphragm opposite to the one face, the piezoelectric element extending across the one end of the pressure chamber in the first direction, and the lower electrode including multiple lower electrode divisions across the one end in the first direction and separated from each other in a second direction orthogonal to the first direction.

### CROSS-REFERENCE TO RELATED APPLICATIONS

This patent application is based on and claims priority pursuant to 35 U.S.C. § 119(a) to Japanese Patent Application No. 2023-047663, filed on Mar. 24, 2023, in the Japan Patent Office, the entire disclosure of which is hereby incorporated by reference herein.

### BACKGROUND

### Technical Field

The present embodiment relates to a piezoelectric actuator, a liquid discharge head, and a liquid discharge apparatus.

### Related Art

A piezoelectric element is used as a drive source of the actuator, and an inkjet actuator is configured using a thin film piezoelectric body.

In a piezoelectric actuator using a thin film piezoelectric body, liquid in a pressure chamber is discharged by driving a piezoelectric element. The pressure chamber is also referred to as a liquid chamber or the like. Stress is concentrated at a boundary portion between an opening and a non-opening of the pressure chamber, and cracks are likely to occur in the piezoelectric element. In particular, cracks are likely to occur in a longitudinal direction where stress is likely to be applied strongly.

### SUMMARY

An aspect of the present disclosure, a piezoelectric actuator includes: a substrate having a pressure chamber elongated in a first direction, the pressure chamber having one end in the first direction; a diaphragm on the substrate and having a one face facing the pressure chamber; and a piezoelectric element including: a lower electrode; a piezoelectric body; and an upper electrode, sequentially laminated on another face of the diaphragm opposite to the one face, the piezoelectric element extending across the one end of the pressure chamber in the first direction, and the lower electrode including multiple lower electrode divisions across the one end in the first direction and separated from each other in a second direction orthogonal to the first direction.

### BRIEF DESCRIPTION OF THE DRAWINGS

A more complete appreciation of embodiments of the present disclosure and many of the attendant advantages and features thereof can be readily obtained and understood from the following detailed description with reference to the accompanying drawings, wherein:

FIG. 1 is a cross-sectional schematic view taken along a longitudinal direction of an example of a piezoelectric actuator and a liquid discharge head according to the present embodiment;

FIG. 2A is a cross-sectional schematic view taken along a lateral direction of an example of a piezoelectric actuator and a liquid discharge head according to the present embodiment;

FIGS. 2B-A and 2B-B are plan schematic views of a main part in an example of the piezoelectric actuator according to the present embodiment;

FIGS. 3A to 3D are plan schematic views of a main part in an example of the piezoelectric actuator according to the present embodiment;

FIG. 4A is another cross-sectional schematic view of a main part in the lateral direction in an example of the piezoelectric actuator according to the present embodiment;

FIG. 4B is an enlarged schematic view of the main part in FIG. 4A;

FIG. 5 is a cross-sectional schematic view taken along a longitudinal direction of a piezoelectric actuator and a liquid discharge head according to a comparative example;

FIG. 6 is a cross-sectional schematic view taken along a lateral direction of a main part of a piezoelectric actuator according to a comparative example;

FIG. 7 is a plan schematic view of a main part of a piezoelectric actuator according to a comparative example;

FIG. 8 is another cross-sectional schematic view taken along a lateral direction of a main part of a piezoelectric actuator according to a comparative example;

FIG. 9A is a plan schematic view of a main part in another example of the piezoelectric actuator according to the present embodiment;

FIGS. 9B-A to 9B-C are plan schematic views for explaining a round shape of a first lower electrode opening or the like;

FIGS. 10A and 10B are cross-sectional schematic views taken along a lateral direction of other main parts in another example of the piezoelectric actuator according to the present embodiment, and are views for explaining a relationship between L and x;

FIGS. 11A and 11B are plan schematic views of a main part in another example of the piezoelectric actuator according to the present embodiment;

FIGS. 12A to 12C are plan schematic views of a main part in another example of the piezoelectric actuator according to the present embodiment;

FIG. 13A-A is a plan schematic view of a main part in another example of the piezoelectric actuator according to the present embodiment;

FIG. 13A-B is an enlarged view of FIG. 13A-A;

FIG. 13A-C is a graph schematically illustrating total opening lengths;

FIG. 13B-A is a plan schematic view of a main part in another example of the piezoelectric actuator according to the present embodiment;

FIG. 13B-B is a graph schematically illustrating total opening lengths;

FIG. 14 is a plan schematic view of a main part in another example of the piezoelectric actuator according to the present embodiment;

FIGS. 15A and 15B are plan schematic views of a main part of another example of the piezoelectric actuator according to the present embodiment, and views for explaining an example of upper electrode openings;

FIG. 15C is a cross-sectional schematic view taken along a lateral direction of the main part;

FIG. 16A is a plan schematic view of a main part of another example of the piezoelectric actuator according to the present embodiment, and a view for explaining another example of upper electrode openings;

FIG. 16B is a cross-sectional schematic view taken along a lateral direction of the main part;

FIG. 17 is a plan schematic view of a main part in another example of the piezoelectric actuator according to the present embodiment, and is a view for explaining an example of a shape of an extended electrode;

FIG. 18 is a perspective schematic view illustrating an example of a liquid discharge apparatus according to the present embodiment; and

FIG. 19 is a side schematic view illustrating an example of the liquid discharge apparatus according to the present embodiment.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DETAILED DESCRIPTION

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

Hereinafter, a piezoelectric actuator, a liquid discharge head, and a liquid discharge apparatus according to the present embodiment will be described referring to the drawings. Note that the following embodiments are not limiting the present disclosure and any deletion, addition, modification, change, etc. can be made within a scope in which a person skilled in the art can conceive including other embodiments, and any of which is included within the scope of the present disclosure as long as the effect and feature of the present disclosure are demonstrated.

According to the present embodiment, it is possible to provide a piezoelectric actuator with improved durability of a piezoelectric element. The present embodiment can be applied to, for example, a liquid discharge head, a liquid discharge apparatus including a liquid discharge head, and the like. The effect of the present embodiment is not limited to the liquid discharge head, and the effect is also exhibited even when the liquid discharge head is used for, for example, an ultrasonic oscillation device, an optical element (for example, a microelectromechanical system (MEMS) mirror), or the like. The piezoelectric actuator of the present embodiment can be used for, for example, an oscillation element of an ultrasonic diagnostic apparatus, an actuator for a MEMS mirror, and the like in addition to the actuator of the liquid discharge head.

### Piezoelectric Actuator and Liquid Discharge Head

The piezoelectric actuator according to the present embodiment includes:
a substrate having an opening;
a diaphragm formed on one face of the substrate and formed in a region including the opening; and
a piezoelectric element in which a lower electrode, a piezoelectric body, and an upper electrode are sequentially laminated on the diaphragm on an opposite side to the substrate,
in which the piezoelectric element has a portion extending from an inner region to an outer region of the opening when viewed from a laminating direction of the piezoelectric element, a direction in this portion from the inner region to the outer region of the opening is defined as a first direction, and
the lower electrode includes multiple first lower electrode divisions separated from each other in a second direction that is a direction along at least one end portion of the opening in the first direction when viewed from the laminating direction.

The liquid discharge head according to the present embodiment includes:
the piezoelectric actuator according to the present embodiment; and
a nozzle member that is bonded to the substrate on an opposite side to the diaphragm of the substrate to form a nozzle corresponding to the opening,
in which a liquid stored in the opening is discharged from the nozzle.

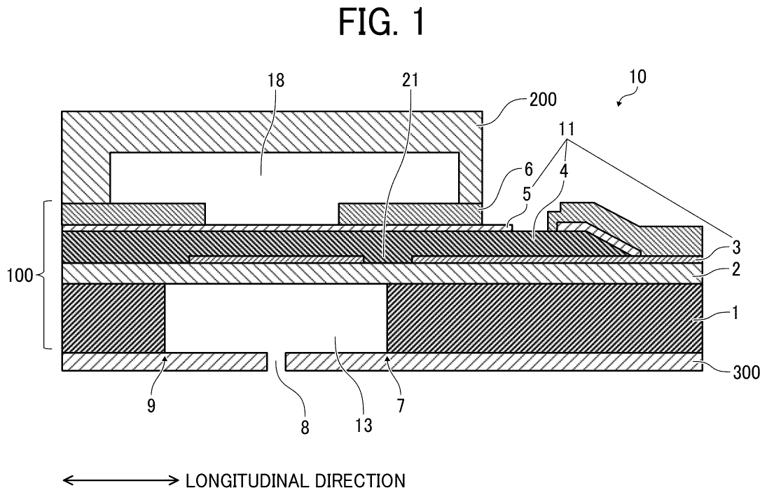

FIG. 1 is a view for explaining an example of the piezoelectric actuator and the liquid discharge head of the present embodiment, and is a cross-sectional schematic view of a pressure chamber 13 in a longitudinal direction.

A liquid discharge head 10 of the present example includes an actuator substrate 100, a nozzle substrate 300, and a support substrate 200. By bonding the actuator substrate 100, the support substrate 200, and the nozzle substrate 300, the liquid discharge head 10 of the present example is obtained.

The piezoelectric actuator of this example includes the actuator substrate 100, a diaphragm 2, and a piezoelectric element 11.

The actuator substrate 100 in this example is provided with the piezoelectric element 11 (may be referred to as a piezoelectric element or the like), the diaphragm 2, the pressure chamber 13, a pressure chamber partition wall 1, and the like. The piezoelectric element 11 generates liquid discharge energy, and the liquid stored in the pressure chamber 13 is discharged by driving the piezoelectric element.

The pressure chamber 13 is an opening provided in the actuator substrate 100, and may be referred to as a pressure chamber, a liquid chamber, an individual chamber, or the like. The pressure chamber 13 may be simply referred to as an opening. The opening means the pressure chamber 13 unless otherwise specified. The substrate means the actuator substrate 100 unless otherwise specified. The substrate having the opening means the actuator substrate 100 having the pressure chamber 13.

The pressure chamber 13 is provided for each nozzle 8 (also referred to as a nozzle hole or the like) and is partitioned by the pressure chamber partition wall 1. The pressure chamber 13 is formed by the actuator substrate 100 and the nozzle substrate 300. However, another substrate forming a flow channel may be disposed between the actuator substrate 100 and the nozzle substrate 300 for rectifying an ink flow. The nozzle substrate may be referred to as a nozzle member.

The piezoelectric element 11 is provided on the diaphragm 2 on the opposite side to the nozzle substrate 300.

The piezoelectric element 11 is configured by sequentially laminating a lower electrode 3, a piezoelectric body 4, and an upper electrode 5 on the diaphragm 2. In this example, the lower electrode 3 is an individual electrode, and the upper electrode 5 is a common electrode, but the present embodiment is not limited thereto, and the lower electrode 3 may be a common electrode, and the upper electrode 5 may be an individual electrode. The piezoelectric body 4 may be referred to as a piezoelectric film or the like.

An extraction electrode 6 is formed on the upper electrode 5, and a voltage is applied to the piezoelectric body 4 by the extraction electrode 6. An insulating protective film may be formed on the upper electrode 5, and in this case, the extraction electrode 6 is electrically connected to the upper electrode 5 through a connection hole in the insulating protective film.

The support substrate 200 is provided with a gap 18 as a region for driving the piezoelectric element.

An example of image formation by the liquid discharge head 10 of the present example will be described.

Each pressure chamber 13 is filled with a liquid, for example, a recording liquid (ink). Based on image data, a controller applies a pulse voltage to the individual electrode corresponding to the nozzle 8 that discharges the liquid by an oscillation circuit. The pulse voltage is not particularly limited, but for example, a pulse voltage of 20 V is used. By applying the pulse voltage, the piezoelectric body 4 contracts in a direction parallel to the diaphragm 2 due to an electrostrictive effect (or also referred to as an inverse piezoelectric effect). As a result, the diaphragm 2 bends so as to be convex in a direction of the pressure chamber 13, pressure in the pressure chamber 13 rapidly rises, and the liquid is discharged from the nozzle 8 communicating with the pressure chamber 13.

After the pulse voltage is applied, the bent piezoelectric body 4 returns to an original position, so that the bent diaphragm 2 returns to an original position. As a result, the pressure inside the pressure chamber 13 becomes a negative pressure as compared with the pressure inside a common chamber. Therefore, the liquid in the common chamber supplied from the outside through a liquid supply port is supplied to the pressure chamber 13. By repeating the above operation, the liquid can be continuously discharged, and an image is formed on a recording medium (for example, paper) disposed to face the liquid discharge head.

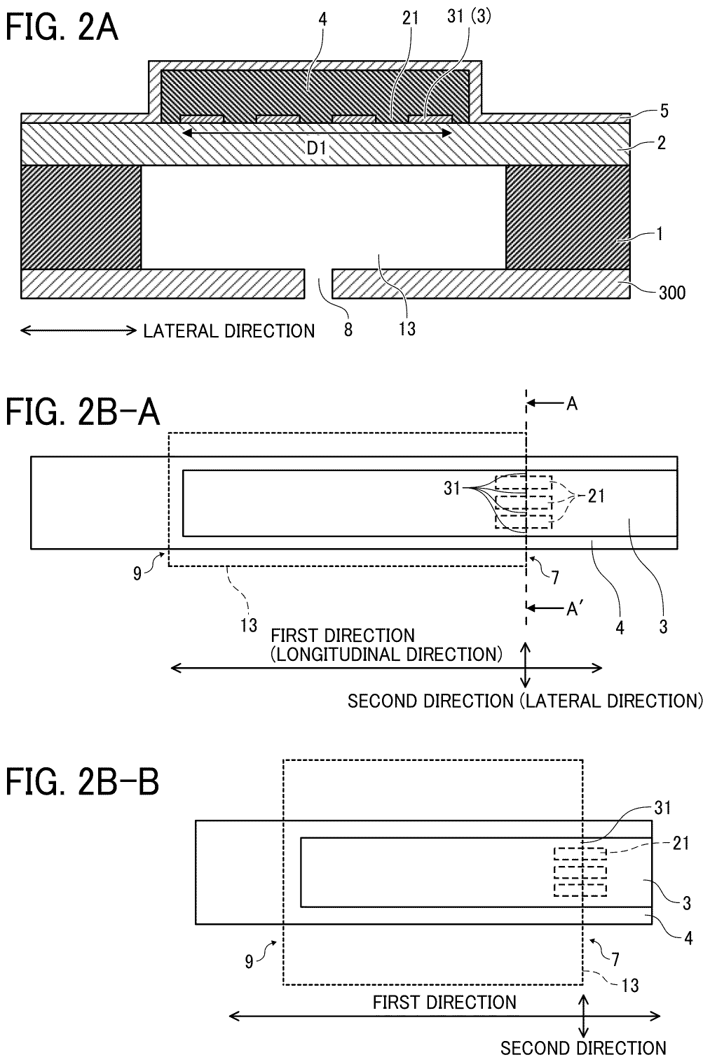

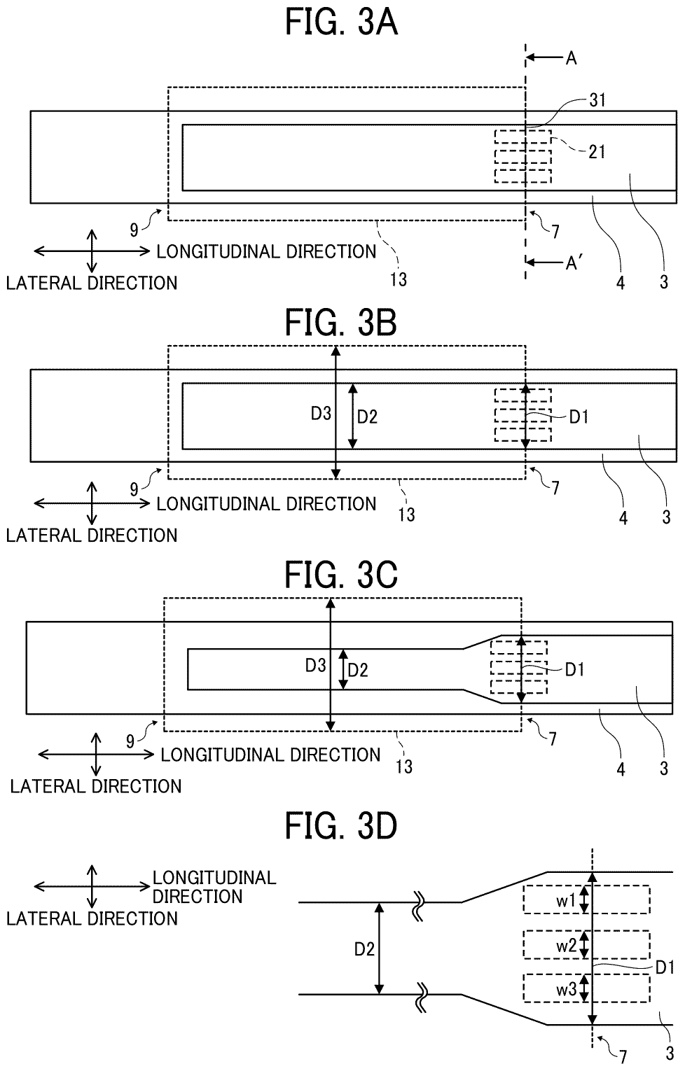

Next, detailed examples of the piezoelectric actuator and the liquid discharge head according to the present embodiment will be described with reference to FIGS. 1 to 3D. FIG. 2A is a cross-sectional schematic view of the pressure chamber 13 in the lateral direction. FIGS. 3A to 3D are plan schematic views of the main part. FIG. 3A is a plan schematic view when viewed from the laminating direction of the actuator substrate 100 and the diaphragm 2, and FIG. 3B is the view illustrating D1 to D2 with respect to FIG. 3A. FIGS. 2B-A and 2B-B are plan schematic views similar to FIGS. 3A to 3D. FIG. 2A corresponds to an AA′ cross-section in FIGS. 2B-A, 2B-B, and 3B.

In FIG. 3A, the lower electrode 3 and the piezoelectric body 4 are indicated by solid lines, and the pressure chamber 13 is indicated by broken lines. The pressure chamber 13 is an opening of the actuator substrate 100. As illustrated, the pressure chamber 13 in the present example has a longitudinal direction and a lateral direction in a plane viewed from the laminating direction of the actuator substrate 100 and the diaphragm 2. Although FIG. 3A illustrates a single piezoelectric element, the piezoelectric actuator of the present embodiment may have multiple piezoelectric elements disposed in an array along the lateral direction of the opening. Further, the piezoelectric actuator may be provided with multiple arrays in which the piezoelectric elements are disposed in the lateral direction.

The lengths of the pressure chamber 13 in the longitudinal direction and the lateral direction can be appropriately adjusted in accordance with the discharging performance of the liquid discharge head. The length in the longitudinal direction is preferably in a range of 300 to 1500 μm, and the length in the lateral direction is preferably in a range of 40 to 300 μm.

Note that the laminating direction of the actuator substrate 100 and the diaphragm 2 or the laminating direction of the piezoelectric element is also referred to as the laminating direction or the like. The laminating direction in the present example may be the same as a laminating direction of the actuator substrate 100 and the nozzle substrate 300, and the laminating direction may be the same as a laminating direction of the actuator substrate 100 and the support substrate 200.

A plane viewed from the laminating direction may be simply referred to as a plane. In a case of being simply referred to as a plan view, it means a plan view as viewed from the laminating direction unless otherwise specified. When viewed from the laminating direction, it may be viewed from the nozzle substrate 300 side to the actuator substrate 100 side, or may be viewed from the support substrate 200 side to the actuator substrate 100 side.

In FIG. 1, one end portion of the pressure chamber 13 in the longitudinal direction is denoted by reference numeral 7. The one end portion of the pressure chamber 13 in the longitudinal direction is referred to as a pressure chamber end portion 7. The pressure chamber end portion 7 may be referred to as a liquid chamber end portion, and the pressure chamber end portion 7 may be referred to as the one end portion. The other end portion in the longitudinal direction of the pressure chamber 13 may also be referred to as a pressure chamber end portion 9, and the pressure chamber end portion 9 may be referred to as the other end portion or the like.

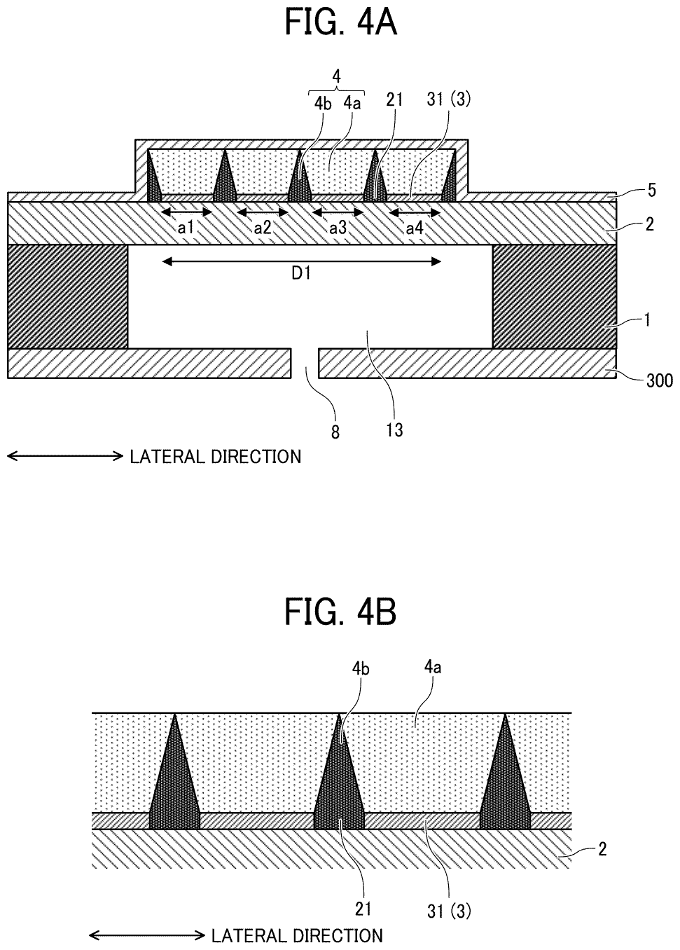

As illustrated in FIGS. 1 and 3A to 3D, the piezoelectric element is provided from the inner region to the outer region of the pressure chamber 13 so as to straddle the pressure chamber end portion 7. As described above, the piezoelectric element straddles the one pressure chamber end portion 7, so that the upper electrode and the lower electrode can be extended to the outside of the pressure chamber 13, and can be easily coupled to a circuit (a driver integrated circuit (IC) or the like) that drives the piezoelectric element. In FIGS. 3A to 3D, the upper electrode 5 illustrated in FIG. 4A is also provided from the inner region to the outer region of the pressure chamber 13 so as to straddle the pressure chamber end portion 7. Since the piezoelectric element is formed across the pressure chamber end portion 7, rigidity of a laminated film at the pressure chamber end portion 7 can be improved, and failure of the piezoelectric element due to stress can be reduced.

The portion where the piezoelectric element straddles the end portion of the pressure chamber can be appropriately selected. In the examples illustrated in FIGS. 1 to 3D, the piezoelectric element is provided, at the pressure chamber end portion 7 and the pressure chamber end portion 9, from the inner region to the outer region of the pressure chamber 13. In other words, the piezoelectric element in this example is provided so as to straddle both end portions in the longitudinal direction. In addition, for example, the piezoelectric element may be provided at only one end portion in the longitudinal direction so as to straddle the end portion. In addition, for example, at an end portion in the lateral direction, the piezoelectric element may be provided from the inner region to the outer region of the pressure chamber 13 so as to straddle the end portion of the pressure chamber.

In other words, to comprehensively describe them, the piezoelectric element in the present embodiment has a portion extending from the inner region of the opening to the outer region of the opening when viewed from the laminating direction of the piezoelectric element.

In this example, as illustrated in FIG. 1, an extraction electrode 6 is also formed across the pressure chamber end portion 7 in the same manner. Since the extraction electrode 6 is formed across the pressure chamber end portion 7, the rigidity of the laminated film at the pressure chamber end portion 7 can be further improved, and failure due to stress can be further prevented.

FIGS. 2B-A and 2B-B are views for describing a first direction and a second direction. The piezoelectric element according to the present embodiment has a portion extending from the inner region to the outer region of the opening when viewed from the laminating direction of the piezoelectric element. In the present embodiment, a direction from the inner region to the outer region of the opening in this portion is defined as the first direction.

A direction along the end portion of the opening in the first direction as viewed from the laminating direction is defined as the second direction. As illustrated in FIGS. 2A to 3D, a direction along the pressure chamber end portion 7 is defined as the second direction.

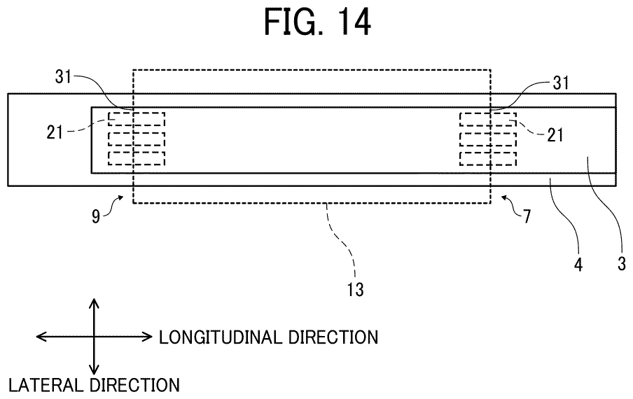

Two end portions (the pressure chamber end portion 7 and the pressure chamber end portion 9) exist in the first direction of the opening (the pressure chamber 13). “At least one end portion of the opening in the first direction” refers to at least one of two end portions (the pressure chamber end portion 7 and the pressure chamber end portion 9). A direction along the pressure chamber end portion 9 may also be the second direction (see FIG. 14).

In FIGS. 2A, 2B-B, and the like, reference numeral of a first lower electrode opening 21 and reference numeral of a first lower electrode division 31 are assigned only to some portions from a viewpoint of visibility. The reference numeral of the first lower electrode opening 21 and the reference numeral of the first lower electrode division 31 may be assigned as in FIG. 2B-A, for example.

In this example, the first direction coincides with the longitudinal direction of the pressure chamber 13, and the second direction coincides with the lateral direction of the pressure chamber 13. In the following description, the longitudinal direction of the pressure chamber 13 is taken as an example of the first direction, and the lateral direction of the pressure chamber 13 is taken as an example of the second direction. However, in the present embodiment, for example, as illustrated in FIG. 2B-B, the pressure chamber 13 (the opening) may not have a longitudinal side and a lateral side. The pressure chamber 13 (the opening) is not limited to a quadrangle in the view (the plan view) viewed from the laminating direction, and may be a polygon other than the quadrangle.

In the present embodiment, the lower electrode 3 includes multiple first lower electrode divisions 31 separated from each other in the lateral direction (the second direction) as viewed from the laminating direction. For example, as illustrated in FIGS. 2A to 3D, the lower electrode 3 includes the multiple first lower electrode divisions 31 separated from each other in the lateral direction. The first lower electrode division 31 is a portion where the lower electrode 3 is present. In the drawings, the first lower electrode division 31 may be denoted by reference numeral 31 (3) to indicate that it is the portion where the lower electrode 3 is present.

Thus, a piezoelectric actuator includes: a substrate having a pressure chamber elongated in a first direction, the pressure chamber having one end in the first direction; a diaphragm on the substrate and having a one face facing the pressure chamber; and a piezoelectric element including: a lower electrode; a piezoelectric body; and an upper electrode, sequentially laminated on another face of the diaphragm opposite to the one face, the piezoelectric element extending across the one end of the pressure chamber in the first direction, and the lower electrode including multiple lower electrode divisions across the one end in the first direction and separated from each other in a second direction orthogonal to the first direction.

Since the multiple first lower electrode divisions 31 is separated from each other in the lateral direction (the second direction), there is a portion where the lower electrode 3 is not present. The portion where the lower electrode 3 is not present is referred to as the first lower electrode opening 21. In other words, the lower electrode 3 has the first lower electrode opening 21 disposed between the multiple first lower electrode divisions 31 adjacent to each other. The first lower electrode opening 21 is illustrated in FIGS. 1, 2A, 2B(a), 2B(b), and the like. As illustrated in FIGS. 1 and 3A to 3D, the lower electrode 3 has the first lower electrode opening 21 that opens from the inner region to the outer region of the pressure chamber 13 so as to straddle the pressure chamber end portion 7 (the one end portion).

When a voltage is applied to the piezoelectric element, stress due to the voltage application is generated in the piezoelectric body 4 in a region where the lower electrode 3 and the upper electrode 5 overlap in the laminating direction. Therefore, the diaphragm 2 is greatly bent as an area in which the lower electrode 3 and the upper electrode 5 overlap in the laminating direction is larger. Accordingly, since an area overlapping the lower electrode 3 and the upper electrode 5 is large and a region where the stress of the piezoelectric body is generated is large, load stress of the piezoelectric body 4 increases.

Since the lower electrode 3 includes the multiple first lower electrode divisions 31 separated from each other, in other words, since the first lower electrode opening 21 is provided, it is possible to reduce a region of the piezoelectric body 4 where the stress is generated by voltage application at the pressure chamber end portion 7. Therefore, the load stress of the piezoelectric body 4 at the pressure chamber end portion 7 can be reduced, and cracks of the piezoelectric body at the pressure chamber end portion 7 can be suppressed. Accordingly, in the present embodiment, a piezoelectric actuator with improved durability of a piezoelectric element can be obtained, and a liquid discharge head with improved durability of a piezoelectric element can be obtained. Thus, in the present embodiment, a highly reliable piezoelectric actuator, a liquid discharge head, and a liquid discharge apparatus can be obtained.

In particular, in the piezoelectric element of FIGS. 3A to 3D, when the pressure chamber 13 has a shape in which a length in the longitudinal direction is shorter than a length in the lateral direction, the load stress of the piezoelectric body 4 at the pressure chamber end portion 7 in the longitudinal direction tends to be larger. The piezoelectric body 4 at the pressure chamber end portion 7 in the longitudinal direction is a region where the lower electrode 3 and the upper electrode 5 overlap with each other, and is provided across the pressure chamber 13 from inside to outside. Although stress is generated in the piezoelectric body 4 by application of the voltage to the piezoelectric element, the piezoelectric body 4 and the diaphragm 2 outside the pressure chamber 13 cannot be deformed because the piezoelectric body 4 and the diaphragm 2 are restrained by the actuator substrate 100. Therefore, since the generated stress cannot be alleviated by deformation, the load stress at the pressure chamber end portion 7 is likely to increase. In the piezoelectric element illustrated in FIGS. 3A to 3D, by providing the first lower electrode opening 21 at the pressure chamber end portion 7, a region where the lower electrode 3 and the upper electrode 5 overlap (a region where stress is generated in the piezoelectric body due to the voltage application) is reduced at the pressure chamber end portion 7 where the load stress is particularly likely to increase, so that durability can be improved.

In the following description, the durability of the piezoelectric body and the durability of the piezoelectric element may be described without distinction. The durability of the piezoelectric body can be improved by preventing the cracks of the piezoelectric body, whereby the durability of the piezoelectric element can be improved.

An action of the first lower electrode opening 21 will be supplementarily described.

As the piezoelectric body 4, for example, lead zirconate titanate (PZT) can be used. In a case where PZT is used as the piezoelectric body 4, for example, PZT (100) oriented in (100) tends to spread in the planar direction as a crystal grows (see FIGS. 4A and 4B to be described later). In a case where the first lower electrode opening 21 is provided in the lower electrode 3, the lower electrode 3 is divided in the lateral direction at the pressure chamber end portion 7. Since the lower electrode 3 is divided in the lateral direction, a cross-sectional area of PZT (100) can be increased without changing a sum of wiring widths. As a result, mechanical durability of the piezoelectric body 4 can be improved as compared with a randomly oriented piezoelectric body.

FIGS. 4A and 4B are cross-sectional schematic views for schematically explaining the crystal orientation of the piezoelectric body 4 in a case where the first lower electrode opening 21 is provided. FIG. 4A is a cross-sectional view similar to FIG. 2A, and FIG. 4B is an enlarged view of the main part of FIG. 4A. Here, an example in which the piezoelectric body 4 is formed using PZT will be described.

In a case where the first lower electrode opening 21 is provided, the piezoelectric body 4 is also formed in the first lower electrode opening 21, and a base of the piezoelectric body 4 in this portion is the diaphragm 2. On the other hand, in a portion where the first lower electrode opening 21 is not provided, the base of the piezoelectric body 4 is the lower electrode 3. The crystal orientation of the piezoelectric body 4 is different between a portion where the first lower electrode opening 21 is provided and a portion where the first lower electrode opening 21 is not provided due to a difference in the base. In the portion where the first lower electrode opening 21 is provided, the piezoelectric body is randomly oriented. In the drawings, a randomly oriented piezoelectric body is denoted by reference numeral 4b. On the other hand, PZT (100) oriented to (100) is formed at the portion where the first lower electrode opening 21 is not provided. In the drawings, PZT (100) is denoted by reference numeral 4a. Hereinafter, a piezoelectric body is also referred to as a piezoelectric body 4a, a piezoelectric body 4b, or the like for distinction.

PZT (100) is known to have a tendency to spread in the planar direction as a crystal grows. Therefore, as illustrated in FIGS. 4A and 4B, the piezoelectric body 4a spreads from the lower electrode 3 toward the upper electrode 5 side. As will be described later with reference to FIG. 8, in a case where the first lower electrode opening 21 is provided as in the present embodiment, the cross-sectional area of PZT (100) can be increased without changing the sum of the lower electrode widths in the lateral direction (the sum of a1 to a4), so that the durability of the piezoelectric body 4 can be improved.

In the present embodiment, a total length (for example, the sum of a1 to a4 in FIG. 4A) of the multiple first lower electrode divisions 31 in the second direction is preferably shorter than a second lower electrode width D2. The second lower electrode width D2 is illustrated in FIGS. 3B to 3D, for example.

In this case, the total length of the lower electrode 3 in the lateral direction at the pressure chamber end portion 7 is shorter than the length (D2) of the lower electrode 3 in the lateral direction at a central portion of the pressure chamber. Therefore, the stress generated in the piezoelectric body at the pressure chamber end portion 7 when a voltage is applied to the piezoelectric element can be reduced with respect to the central portion of the pressure chamber 13. As a result, the durability of the piezoelectric element can be further improved.

It can also be said that this definition is the same as D5<D2 to be described later.

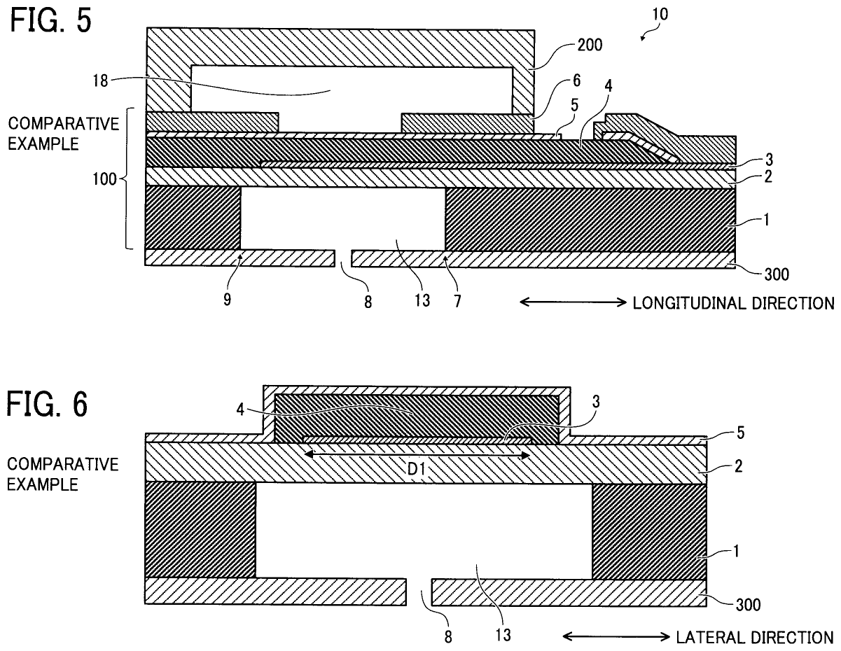

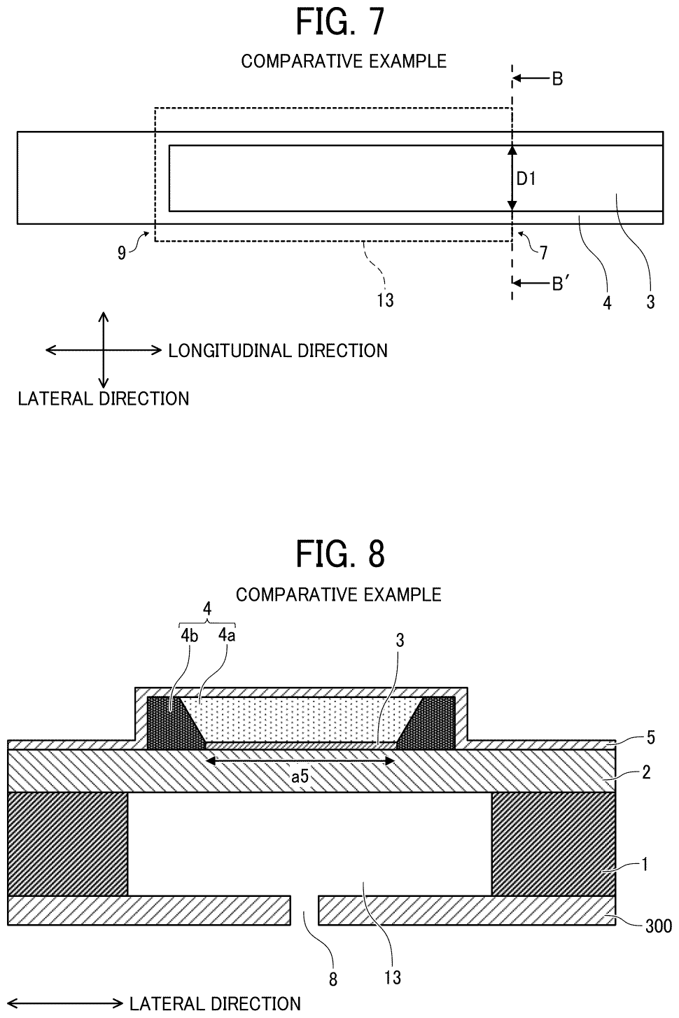

FIGS. 5 to 8 are views illustrating comparative examples not included in the present embodiment. FIG. 5 is a cross-sectional schematic view taken along the longitudinal direction, and is a view similar to FIG. 1. FIG. 6 is a cross-sectional schematic view taken along the lateral direction of the pressure chamber end portion 7, and is a view similar to FIG. 2A. FIG. 7 is a plan schematic view seen from the laminating direction, and is a view similar to FIGS. 3A to 3D. FIG. 6 corresponds to a BB′ cross-sectional view of FIG. 7. FIG. 8 is a cross-sectional schematic view for schematically explaining the crystal orientation of the piezoelectric body 4, and is a view similar to FIGS. 4A and 4B.

As illustrated, in the comparative examples, the first lower electrode opening 21 is not provided. Therefore, since the length (corresponding to the overlapping area) in the lateral direction in which the upper electrode 5 and the lower electrode 3 overlap at the pressure chamber end portion 7 becomes as long as D1, the load stress increases in the piezoelectric body 4 due to an increase in the region where the stress is generated by the voltage application, and the cracks occur in the piezoelectric body 4 at the portion where the load stress increases. In the comparative examples, the cracks of the piezoelectric body 4 at the pressure chamber end portion 7 cannot be prevented, and the durability of the piezoelectric element is poor.

As described above, when a voltage is applied to the piezoelectric element, the stress is generated in the piezoelectric body in the region where the lower electrode 3 and the upper electrode 5 overlap in the laminating direction. Thus, by shortening the sum of the widths in the lateral direction of the lower electrode 3 at the pressure chamber end portion 7 (the sum of the wiring widths), it is possible to reduce the region where the stress is generated at the pressure chamber end portion 7, and to reduce the load stress of the piezoelectric body 4. FIGS. 4A and 4B illustrate an example in which the first lower electrode openings 21 are provided to shorten the sum of the lower electrode widths in the lateral direction (the sum of the wiring widths). FIG. 8 illustrates an example in which the first lower electrode opening 21 is not provided in the lower electrode 3, and the sum of the lower electrode widths in the lateral direction (the sum of the wiring widths) is shortened.

Here, a comparison of FIGS. 4A and 4B with FIG. 8 will be described. The sum of the lengths a1 to a4 in the lateral direction of the divided lower electrode 3 illustrated in FIG. 4A is also referred to as the sum of the lower electrode widths in the lateral direction of the lower electrode 3 at the pressure chamber end portion 7 or the sum of the wiring widths. The sum of the wiring widths of the lower electrode 3 (the sum of a1 to a4) in FIG. 4A is equal to the length a5 of the lower electrode 3 at the pressure chamber end portion 7 in FIG. 8. Accordingly, the sums of the regions in which the stress is generated by the voltage application in FIG. 4A and FIG. 8 are substantially the same. However, in FIG. 4A, since the first lower electrode openings 21 are provided, a stress generation range is dispersed in the lateral direction, so that the generated stress hardly concentrates, and the load stress of the piezoelectric body 4 can be further reduced.

The sum of the cross-sectional areas of PZT (100) in FIGS. 4A and 4B (the cross-sectional areas of the piezoelectric body 4a) is larger than the sum of the cross-sectional areas of PZT (100) in FIG. 8 (the cross-sectional areas of the piezoelectric body 4a).

Therefore, in the present embodiment (for example, the example illustrated in FIGS. 4A and 4B), the sum of the cross-sectional areas of PZT (100) can be increased as compared with the comparative example (the example illustrated in FIG. 8) without changing the sum of the wiring widths of the lower electrode 3 (while equalizing the stress generated in the piezoelectric body when the voltage is applied). In the present embodiment, since the multiple first lower electrode openings 21 is provided, the lower electrode 3 is provided so as to be dispersed in the lateral direction, and crystallinity of the piezoelectric body 4 can be excellently maintained. As a result, the durability of the piezoelectric body 4 can be improved.

In the example illustrated in FIGS. 1 to 3D, three first lower electrode openings 21 are illustrated, but the present embodiment is not limited thereto. The number of first lower electrode openings 21 may be one, two, or more than three. Another example of the first lower electrode opening 21 will be described later. Considering FIGS. 4A and 4B, from a viewpoint of increasing the sum of the cross-sectional areas of PZT (100), it is preferable that there are more than one first lower electrode opening 21.

In the present embodiment, as illustrated in FIGS. 3B and 3C, it is preferable that D1 and D2 satisfy a predetermined relationship. This will be described below.

When viewed from the laminating direction, a length of the lower electrode 3 in the lateral direction (the second direction) at the pressure chamber end portion 7 (the one end portion) is defined as a first lower electrode width D1, and a length of the lower electrode 3 in the lateral direction at the central portion in the longitudinal direction (the first direction) of the pressure chamber 13 (the opening) is defined as the second lower electrode width D2.

Here, D1≥D2 is preferably satisfied. The central portion in the longitudinal direction of the pressure chamber 13 also includes a substantially central portion in the longitudinal direction. In the example illustrated in FIG. 3B, D1=D2.

In a case where D1≥D2 is satisfied, the area of the piezoelectric body 4 having (100) preferential orientation in the lateral direction at the pressure chamber end portion 7 can be made equal to or larger than the area of the piezoelectric body 4 having the (100) preferential orientation in the lateral direction in the pressure chamber 13.

As a result, the crystallinity of the piezoelectric body 4 can be improved, and the mechanical durability can be improved.

On the other hand, in a case where D1<D2, the area of the (100) preferential orientation of the piezoelectric body in the lateral direction in a drive region of the piezoelectric element decreases. Therefore, the durability may be inferior to the case of satisfying D1≥D2. When the width of the lower electrode 3 is narrowed outside the pressure chamber 13, a ratio of the piezoelectric body 4b having weak strength, which is crystal-grown in a portion where the lower electrode 3 is not provided, increases at the pressure chamber end portion 7. The piezoelectric body 4 may be damaged around the pressure chamber end portion 7.

The example illustrated in FIG. 3C satisfies D1>D2. Even in this case, the area of the piezoelectric body 4 having the (100) preferential orientation in the lateral direction at the pressure chamber end portion 7 can be made equal to or larger than the area of the piezoelectric body 4 having the (100) preferential orientation in the lateral direction in the pressure chamber 13. As a result, the mechanical durability can be improved. By providing the first lower electrode opening 21 at the pressure chamber end portion 7, the stress generated in the piezoelectric body during voltage application can be reduced, so that durability can be improved.

As in the example illustrated in FIG. 3C, in a case where the relationship D1>D2 is satisfied, a length D5 obtained by subtracting the sum of the lengths in the lateral direction of the first lower electrode openings 21 from the length D1 in the lateral direction of the lower electrode at the pressure chamber end portion 7 is more preferably shorter than D2. In the example of FIG. 3C, when the lengths of the three first lower electrode openings 21 in the lateral direction of the pressure chamber 13 are w1, w2, and w3 (see FIG. 3D), the following relationship is preferably established.

$$\begin{matrix}When D 5 = D 1 - w 1 - w 2 - w 3 , \\ D 5 < D 2.\end{matrix}$$

With such a relationship, the total length D5 (=D1−w1−w2−w3) of the lower electrode 3 in the lateral direction at the pressure chamber end portion 7 is shorter than the length (D2) of the lower electrode 3 in the lateral direction at the central portion of the pressure chamber. Therefore, the stress generated in the piezoelectric body at the pressure chamber end portion 7 when a voltage is applied to the piezoelectric element can be reduced with respect to the central portion of the pressure chamber 13. As a result, the durability of the piezoelectric element can be further improved.

FIG. 3D is an enlarged view of the main part of FIG. 3C, and is a view for describing the above relationship. As illustrated, the lengths of the three first lower electrode openings 21 in the lateral direction of the pressure chamber 13 are indicated by w1, w2, and w3, respectively.

In the present embodiment, when viewed from the laminating direction, a length of the lower electrode 3 in the lateral direction (the second direction) at the central portion in the longitudinal direction (the first direction) of the pressure chamber 13 (the opening) is defined as the second lower electrode width D2, and a length of the pressure chamber 13 in the lateral direction at the central portion in the longitudinal direction of the pressure chamber 13 is defined as an opening width D3.

Here, D2<D3 is preferably satisfied. The central portion in the longitudinal direction of the pressure chamber 13 also includes a substantially central portion in the longitudinal direction. The examples illustrated in FIGS. 3B and 3C satisfy D2<D3.

In a case where D2<D3 is satisfied, it is possible to prevent the piezoelectric body 4 from being deformed by application of an electric field at a lateral end portion of the pressure chamber 13. Therefore, as compared with the case of D2>D3, it is possible to prevent a strong stress from being applied to the piezoelectric body 4 at the lateral end portion of the pressure chamber.

In the present embodiment, it is more preferable to satisfy D1≥D2 and D2<D3. In this case, since the stress generated in the piezoelectric body 4 at the lateral end portion of the pressure chamber 13 can be reduced, the durability can be improved.

Examples of preferred D1, D2, and D3 in the present embodiment include D1 and D2 being 40 μm, D3 being 70 μm, and the width of the piezoelectric body 4 in the lateral direction being 60 μm, which is a value between D2 and D3. With such a relationship, the durability of the piezoelectric actuator can be improved.

The length of the first lower electrode opening 21 in the longitudinal direction can be appropriately selected, but is preferably a certain length. In a case where the length of the first lower electrode opening 21 in the longitudinal direction is too short, the stress generated in the piezoelectric body 4 may not be sufficiently alleviated, and the cracks may not be sufficiently prevented. On the other hand, in a case where the length of the first lower electrode opening 21 in the longitudinal direction is too long, displacement amount of the piezoelectric element or the diaphragm 2 decreases, and a liquid discharge speed may decrease.

The length of the first lower electrode opening 21 in the longitudinal direction is preferably 20% or less and 5% or more of the length of the pressure chamber 13 in the longitudinal direction. The first lower electrode opening 21 of the present embodiment may be 40 μm in the longitudinal direction and 2 μm in the lateral direction.

Next, an example of a planar shape of the first lower electrode opening 21 and the like will be described.

In the present embodiment, the planar shape of the first lower electrode opening 21 can be appropriately selected. The planar shape of the first lower electrode opening 21 is, for example, a rectangular shape having a longitudinal side and a lateral side as illustrated in FIGS. 3A to 3D and the like, but is not limited thereto.

The planar shape of the first lower electrode opening 21 is preferably a round shape.

When the first lower electrode opening 21 has a round shape, it is possible to alleviate a stress fluctuation generated at an opening end portion of the first lower electrode opening 21.

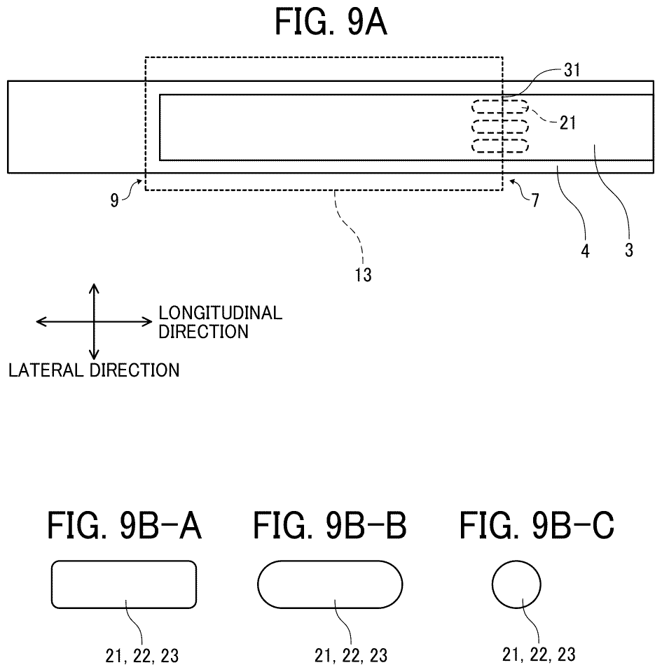

FIG. 9A is a plan schematic view for explaining an example of the present example. As illustrated, the first lower electrode openings 21 have a round shape. All the first lower electrode openings 21 may have a round shape, or some of the first lower electrode openings 21 may have a round shape.

The round shape of the first lower electrode opening 21 can be appropriately selected. The round shape will be described with reference to FIGS. 9B-A to 9B-C. FIGS. 9B-A to 9B-C are views illustrating examples of the planar shape of the first lower electrode opening 21.

Examples of the round shape include shapes in which four corner portions of the first lower electrode opening 21 have an R shape as illustrated in FIGS. 9B-A and 9B-B. FIG. 9B(a) illustrates an example of a case where the four corner portions of the first lower electrode opening 21 have an R shape, and straight portions are provided between the corner portions. FIG. 9B-A is an example of a case where there are four straight portions.

FIG. 9B-B illustrates an example where four corner portions of the first lower electrode opening 21 have an R shape, and there are two straight portions provided between the corner portions. As illustrated in FIGS. 9B-A and 9B-B, a size of the round R shape can be appropriately changed.

In addition, the size of the R shape may be different at each corner portion.

FIG. 9B-C illustrates an example of a case where four corner portions of the first lower electrode opening 21 have an R shape, and there is no straight portion provided between the corner portions. FIG. 9B-C illustrates an example in which the first lower electrode opening 21 is circular. As described above, the case where the first lower electrode opening 21 is circular is also included in the case where the first lower electrode opening 21 has a round shape.

In FIGS. 9B-A to 9B-C, reference numerals are 21, 22, and 23. In other words, the planar shape of a second lower electrode opening 22 (to be described later) may have a round shape, and the planar shape of an upper electrode opening 23 (to be described later) may have a round shape. When the planar shape of the second lower electrode opening 22 and the planar shape of the upper electrode opening 23 are a round shape, it is possible to alleviate the stress fluctuation generated at the opening end portion, which is preferable. A radius of curvature of the round shape can be arbitrarily set, but is preferably in a range of 0.3 to 2.5 μm.

Next, an example of a relationship between the first lower electrode opening 21 and the piezoelectric body 4 will be described.

In a case where PZT is used as the piezoelectric body 4, PZT (100) having the (100) orientation has a property of spreading in the planar direction of film thickness as compared with other orientations. As a result of examination, in PZT (100), an angle θ between the laminating direction and a spreading direction in the planar direction was about 35° at the maximum.

Therefore, in order to cover a PZT orientation on the upper electrode 5 side with the (100) plane, d, which is ½ of a length L of the first lower electrode opening 21 in the lateral direction, and a thickness x of the piezoelectric body 4 preferably satisfy the relationship of tan 35°≥d/x, that is, the relationship of d≤0.7x. When these relationships are expressed as a relationship between the length L of the first lower electrode opening 21 in the lateral direction and the thickness x of the piezoelectric body 4, L≤1.4x.

In other words, a distance L between the two first lower electrode divisions 31 adjacent to each other in the second direction (the lateral direction) and the thickness x of the piezoelectric body 4 preferably satisfy the following relationship:

L≤1.4x.

In a case where this relationship is defined using the first lower electrode opening 21, it can be defined that the length L of the first lower electrode opening 21 in the lateral direction and the thickness x of the piezoelectric body 4 preferably satisfy the following relationship:

L≤1.4x.

In a case where this relationship is satisfied, the PZT orientation on the upper electrode 5 side can be covered with the (100) plane, and the durability of the piezoelectric body 4 is improved.

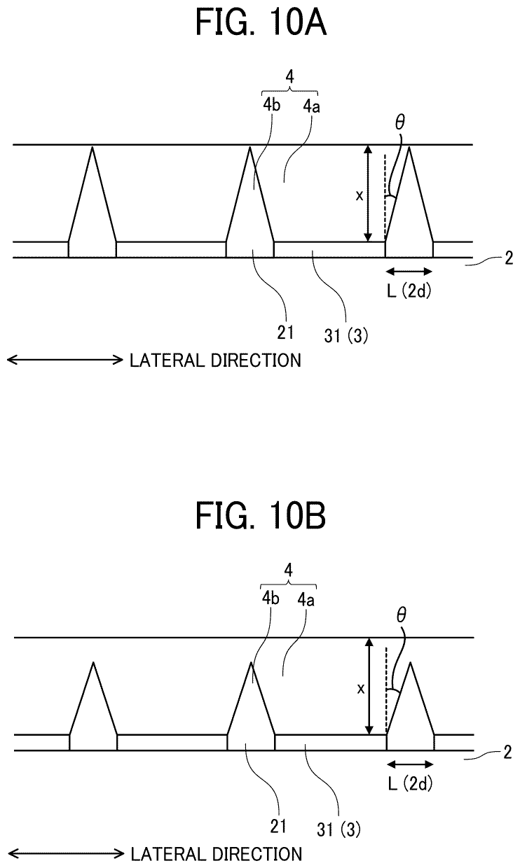

FIGS. 10A and 10B are cross-sectional schematic views for explaining the relationship L≤1.4x, are cross-sectional views similar to FIGS. 4A and 4B, and are views for explaining the angle θ between the laminating direction and the spreading direction in the planar direction.

As illustrated, L is a length of the first lower electrode opening 21 in the lateral direction, and ½ of L is d. x is the thickness of the piezoelectric body 4. θ is an angle between the laminating direction and the spreading direction of the piezoelectric body 4 in the planar direction. As illustrated in FIG. 10A, tan 0 is d/x. FIG. 10A is a view illustrating L=1.4x, and FIG. 10B is a view illustrating L<1.4x.

In order to satisfy the relationship of L≤1.4x, it is sufficient to appropriately adjust the relationship between the size of the opening of the first lower electrode opening 21 and the film thickness of the piezoelectric body 4. When the thickness of the piezoelectric body 4 varies, the thicknesses of several portions may be obtained and averaged. In order to determine whether L and x satisfy the above relationship, for example, the cross-section is observed by a scanning electron microscope (SEM).

Next, an example of the second lower electrode opening will be described.

In the present embodiment, an opening may be provided in the lower electrode 3 in addition to the first lower electrode opening 21.

In the present example, the lower electrode 3 includes at least three or more first lower electrode divisions 31, and multiple second lower electrode divisions 32 that is formed in the inner region of the pressure chamber 13 (the opening) when viewed from the laminating direction, is separated from each other in the second direction, and is provided to be separated from the first lower electrode divisions 31 in the first direction. In addition, each of the second lower electrode divisions 32 is disposed so as to overlap with a region between the corresponding two adjacent first lower electrode divisions 31 in the first direction.

Similarly to the first lower electrode division 31, the second lower electrode division 32 is a portion where the lower electrode 3 is present. In the drawings, the second lower electrode division 32 may be denoted by reference numeral 32 (3) to indicate that it is the portion where the lower electrode 3 is present.

Thus, the lower electrode includes: the multiple lower electrode divisions disposed across the one end of the pressure chamber in the first direction, the multiple lower electrode divisions including two or more lower electrodes; and another multiple lower electrode divisions disposed inside the pressure chamber in the first direction, wherein said another multiple lower electrode divisions are: separated from each other in the second direction; and separated from the multiple lower electrode divisions in the first direction, and one of said another multiple lower electrode divisions is disposed between two of the multiple lower electrode divisions adjacent to each other.

In a case where the second lower electrode opening 22 is defined using the first lower electrode opening 21, for example, it can be defined as follows. The lower electrode 3 includes the multiple first lower electrode openings 21 and multiple the second lower electrode openings 22 which are openings in the inner region of the pressure chamber 13 (the opening) when viewed from the laminating direction and do not overlap with the first lower electrode openings 21. Similarly to the first lower electrode opening 21, the second lower electrode opening 22 is a portion where the lower electrode 3 is not present.

The lower electrode 3 is divided at a place where the load stress is generated, in other words, the multiple second lower electrode divisions 32 is provided, in other words, the second lower electrode opening is provided, so that the durability of the piezoelectric body 4 can be improved.

In addition, since the lower electrode 3 has the multiple second lower electrode divisions 32, in other words, has the second lower electrode opening 22, it is possible to reduce a difference in stress generated in the piezoelectric body 4 around the pressure chamber end portion 7 as compared with a case where the lower electrode 3 does not have the second lower electrode opening 22. When viewed from the laminating direction, in the piezoelectric body 4, a difference occurs in the stress generated between a region where the first lower electrode opening 21 is provided and a region where the first lower electrode opening 21 is not provided in the pressure chamber 13. In the region where the first lower electrode opening 21 is provided, the area where the lower electrode 3 and the upper electrode 5 overlap with each other is relatively small, so that the stress generated in the piezoelectric element when a voltage is applied is reduced. When the second lower electrode opening 22 is provided, the stress generated in the piezoelectric body 4 around the pressure chamber end portion 7 can be reduced, so that a difference in the stress generated in the piezoelectric body 4 can be reduced. In other words, it is possible to reduce local fluctuations in the stress generated in the piezoelectric body 4 near the pressure chamber end portion 7.

The shape, number, arrangement, and the like of the second lower electrode openings 22 can be appropriately selected.

The planar shape of the second lower electrode opening 22 is preferably a round shape as described in FIGS. 9B-A to 9B-C. When the planar shape of the second lower electrode opening 22 is a round shape, it is possible to alleviate the stress fluctuation generated at the opening end portion of the second lower electrode opening 22.

The openings of the lower electrode 3 formed of the multiple first lower electrode openings and the multiple second lower electrode openings are preferably disposed in a staggered manner in at least one of the longitudinal direction and the lateral direction. In such an opening of the lower electrode 3, the lower electrode 3 and the upper electrode 5 do not overlap in the laminating direction. Therefore, even when a voltage is applied to the piezoelectric element, no electric field is applied to the piezoelectric body located in the opening of the lower electrode 3, so that no stress is generated. As described above, a region where the lower electrode 3 and the upper electrode 5 do not overlap with each other does not generate stress, and thus is referred to as a non-driving portion or a non-active portion of the piezoelectric element. On the other hand, a region where the lower electrode 3 and the upper electrode 5 overlap in the laminating direction is referred to as a driver or an active portion of the piezoelectric element.

In this way, a non-drive region of the piezoelectric element is dispersed, the stress generated in the piezoelectric body can be dispersed, and the durability of the piezoelectric element can be further improved.

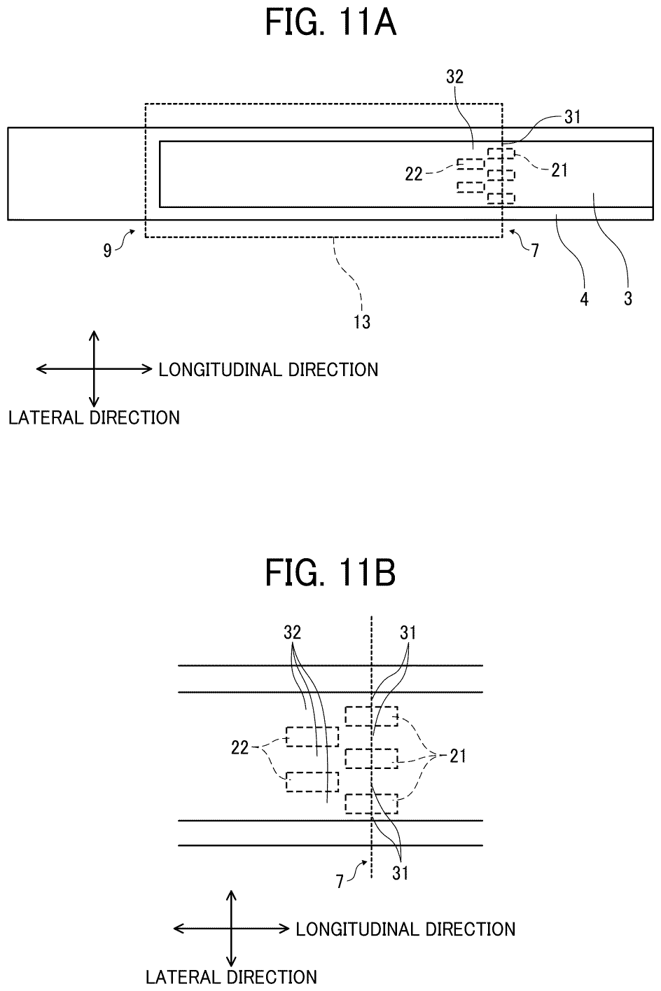

FIGS. 11A and 11B are plan schematic views for explaining the example of a staggered arrangement. As illustrated, the first lower electrode openings 21 and the second lower electrode openings 22 are disposed in a staggered manner. In the illustrated example, the openings of the lower electrode 3 are disposed in a staggered manner in the longitudinal direction and the lateral direction.

Next, the second lower electrode division 32 and the second lower electrode opening 22 will be described using still another example.

Also in the present example, the lower electrode 3 has the second lower electrode opening 22 which is an opening in the inner region of the pressure chamber 13 (the opening) when viewed from the laminating direction and does not overlap with the first lower electrode opening 21. In this example, the length of the second lower electrode opening 22 in the longitudinal direction is shorter than the length of the first lower electrode opening 21 in the longitudinal direction.

Since the length of the second lower electrode opening 22 in the longitudinal direction is shorter than the length of the first lower electrode opening 21 in the longitudinal direction, it is possible to prevent inhibition of driving of the piezoelectric element in the pressure chamber 13. In other words, since the length of the second lower electrode opening 22 in the longitudinal direction is shorter than the length of the first lower electrode opening 21 in the longitudinal direction, it is possible to suppress a decrease in the driving amount of the entire piezoelectric element while reducing a local change in the stress generated.

In the present example, it is preferable that multiple the second lower electrode openings 22 is provided, the length in the longitudinal direction increases from a center side toward an end portion side of the pressure chamber 13 (the opening) in the longitudinal direction, and the length in the longitudinal direction of the second lower electrode opening 22 does not exceed the length in the longitudinal direction of the first lower electrode opening 21.

In this way, the stress generated in the piezoelectric body 4 can be gradually reduced toward the pressure chamber end portion 7. By gradually reducing the stress, it is possible to suppress local increase of the stress generated in the piezoelectric body 4, and it is possible to suppress generation of a portion where a stress load increases.

The lower electrode includes another multiple lower electrode divisions inside the pressure chamber in the first direction, said another multiple lower electrode divisions are: separated from each other in the second direction, and separated from the multiple lower electrode divisions in the first direction, and a total length of said another multiple lower electrode divisions in the second direction is longer than a total length of the multiple lower electrode divisions in the second direction.

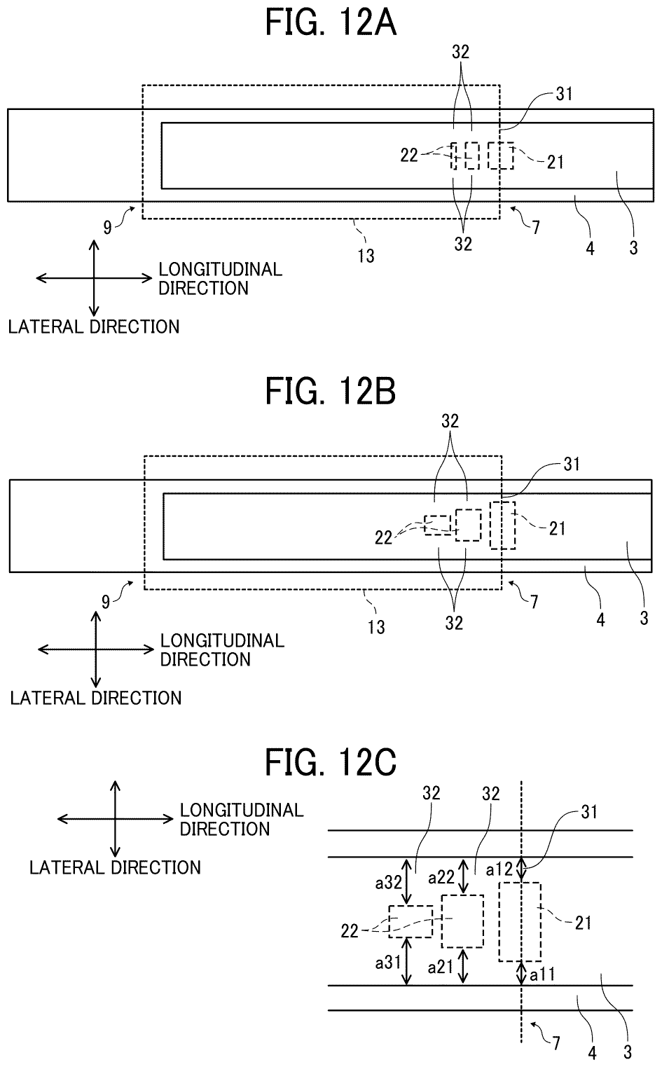

FIG. 12A is a plan schematic view for explaining the present example. As illustrated, the length of the second lower electrode opening 22 in the longitudinal direction increases from the center side toward the end portion side of the pressure chamber 13 in the longitudinal direction. The length of the second lower electrode opening 22 in the longitudinal direction does not exceed the length of the first lower electrode opening 21 in the longitudinal direction. In the illustrated example, the number of the second lower electrode openings 22 is two, but is not limited thereto, and can be appropriately changed.

Next, the second lower electrode division 32 and the second lower electrode opening 22 will be described using still another example.

Also in the present example, the lower electrode 3 has the second lower electrode opening 22 which is an opening in the inner region of the pressure chamber 13 (the opening) when viewed from the laminating direction and does not overlap with the first lower electrode opening 21. In this example, the length of the second lower electrode opening 22 in the lateral direction is shorter than the length of the first lower electrode opening 21 in the lateral direction.

Since the length of the second lower electrode opening 22 in the lateral direction is shorter than the length of the first lower electrode opening 21 in the lateral direction, it is possible to prevent inhibition of driving of the piezoelectric element in the pressure chamber 13. In other words, since the length of the second lower electrode opening 22 in the lateral direction is shorter than the length of the first lower electrode opening 21 in the lateral direction, it is possible to suppress a decrease in the driving amount of the entire piezoelectric element while reducing the local change in the stress generated.

FIG. 12B is a plan schematic view for explaining the present example. As illustrated, the length of the second lower electrode opening 22 in the lateral direction increases from the center side toward the end portion side of the pressure chamber 13 in the longitudinal direction. The length of the second lower electrode opening 22 in the lateral direction does not exceed the length of the first lower electrode opening 21 in the lateral direction. In the illustrated example, the number of the second lower electrode openings 22 is two, but is not limited thereto, and can be appropriately changed.

FIG. 12B is defined with reference to FIG. 12C. FIG. 12C is an enlarged view of the main part of FIG. 12B. As illustrated, a total length (a21+a22 in the drawing) of the multiple second lower electrode divisions 32 in the lateral direction (the second direction) is longer than a total length (a11+a12 in the drawing) of the multiple first lower electrode divisions 31 in the lateral direction. As a result, this makes it possible to suppress a decrease in the driving amount of the entire piezoelectric element while reducing the local change in the stress generated.

The definitions for FIGS. 12B and 12C will be described again. The lower electrode 3 has the second lower electrode divisions 32 in the inner region of the opening when viewed from the laminating direction. The multiple second lower electrode divisions 32 is provided in the second direction, is separated from each other in the second direction, and is separated from the first lower electrode divisions 31 in the first direction. The total length of the multiple second lower electrode divisions 32 in the second direction is longer than the total length of the multiple first lower electrode divisions 31 in the second direction.

Further, in the present example, it is preferable that the total length of the second lower electrode divisions 32 in the lateral direction (the second direction) reduces from the center side toward the end portion side of the pressure chamber 13 (the opening) in the longitudinal direction (the first direction), and the total length of the second lower electrode divisions 32 in the second direction is equal to or less than the total length of the first lower electrode divisions 31 in the second direction.

In this way, the stress generated in the piezoelectric body 4 can be gradually reduced toward the pressure chamber end portion 7. By gradually reducing the stress, it is possible to suppress local increase of the stress generated in the piezoelectric body 4, and it is possible to suppress generation of a portion where the stress load increases.

The total length of said another multiple lower electrode divisions (second lower electrode divisions 32) in the second direction decreases from a center of the pressure chamber toward the one end of the pressure chamber in the first direction, and the total length of said another multiple lower electrode divisions (second lower electrode divisions 32) in the second direction is equal to or larger than the total length of the multiple lower electrode divisions (first lower electrode divisions 31) in the second direction.

FIGS. 12B and 12C illustrate that the total length of the second lower electrode divisions 32 in the lateral direction decreases from the center side toward the end portion side in the longitudinal direction. For example, as illustrated in FIG. 12C, a21+a22 in the drawing, which is an example of the total length on the end portion side, is smaller than a31+a32 in the drawing, which is an example of the total length on the center side.

Next, the second lower electrode division 32 and the second lower electrode opening 22 will be described using still another example.

In this example, the lower electrode 3 includes a first lower electrode opening 21 disposed between the multiple first lower electrode divisions 31 adjacent to each other, and a second lower electrode opening 22 disposed on the center side in the longitudinal direction (the first direction) of the pressure chamber 13 (the opening) than the first lower electrode opening 21. Multiple the first lower electrode openings 21 and multiple the second lower electrode openings 22 are provided. The total length of the multiple first lower electrode openings 21 in a cross-section in the lateral direction is defined as a first total opening length, and the total length of the multiple second lower electrode openings 22 in the cross-section in the lateral direction is defined as a second total opening length. At this time, the second total opening length is equal to or less than the first total opening length, and tends to increase from the center side toward the end portion side of the pressure chamber 13 in the longitudinal direction.

In this way, a change in the stress generated in the piezoelectric body 4 can be gradually reduced toward the pressure chamber end portion 7, and a change in the stress at the pressure chamber end portion 7 can be further reduced.

The multiple lower electrode divisions include first multiple openings separated in the second direction to define the multiple lower electrode divisions, said another multiple lower electrode divisions include second multiple openings separated in the second direction to define said another multiple lower electrode divisions, a total length of the second multiple openings in the second direction is equal to or less of a total length of the first multiple openings in the second direction, and the total length of the second multiple openings increases from a center of the pressure chamber toward the one end of the pressure chamber in the first direction.

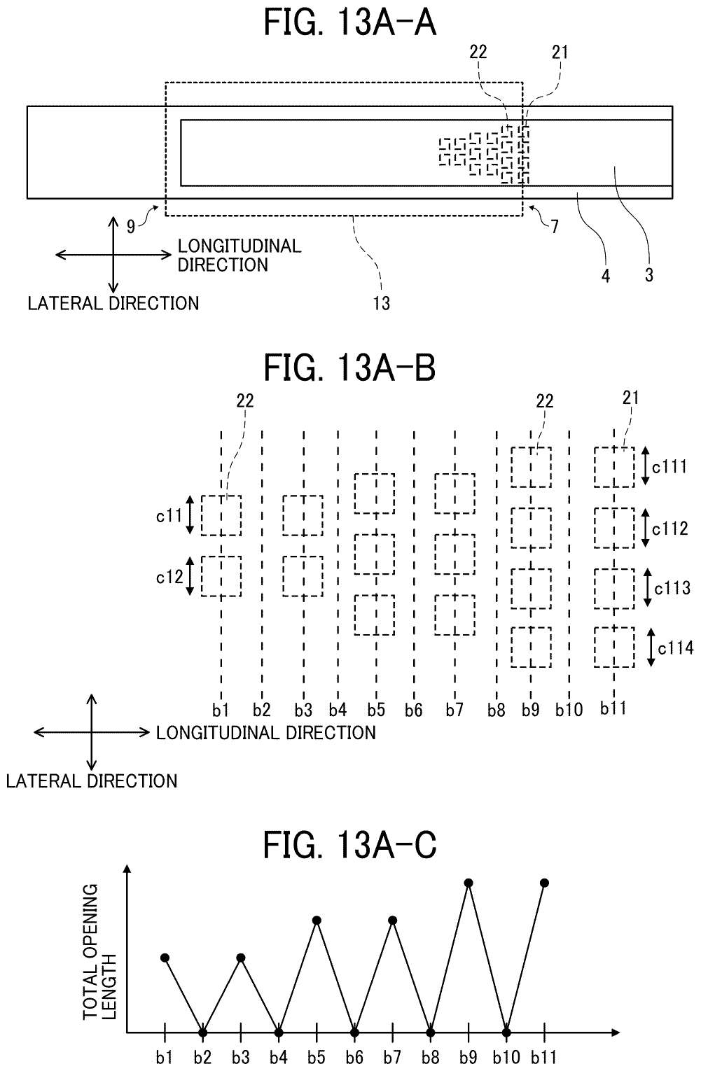

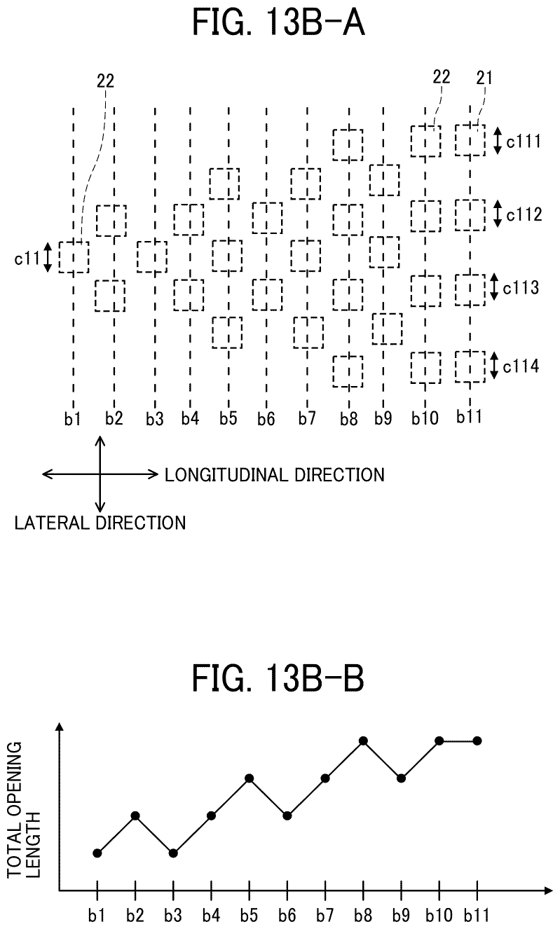

FIGS. 13A-A to 13B-B are views and graphs for explaining the present example, but the numbers and arrangements of the second lower electrode openings 22 are different between the example illustrated in FIGS. 13A-A to 13A-C and the example illustrated in FIGS. 13B-A and 13B-B. First, an example of FIGS. 13A-A to 13A-C will be described.

FIG. 13A-A is a plan schematic view of the main part, and is a view similar to FIGS. 3A to 3D. FIG. 13A-B is an enlarged view of FIG. 13A-A. As illustrated, the multiple second lower electrode openings 22 is provided, and the number of second lower electrode openings 22 disposed in the lateral direction increases from the center side toward the end portion side of the pressure chamber 13.

In FIG. 13A-B, points considering the cross-section in the lateral direction are indicated by broken lines b1 to b11. The lengths, in the lateral direction, of the second lower electrode openings 22 in the cross-section in the lateral direction are denoted by c11, c12, and the like. In other words, the lengths, in the lateral direction, of the second lower electrode openings 22 in a cross-section b1 are c11 and c12, and a total value of c11 and c12 is the second total opening length in the cross-section b1.

In the example illustrated in FIG. 13A-B, a cross-section b11 corresponds to the first lower electrode openings 21, and the lengths, in the lateral direction, of the first lower electrode openings 21 in the cross-section in the lateral direction are indicated by c111 to c114. Therefore, a total value of c111 to c114 is the first total opening length.

FIG. 13A-C is a graph plotting the first total opening length and the second total opening lengths in FIG. 13A-B. The total opening length in the graph represents the first total opening length and the second total opening lengths. As illustrated, the individual second total opening lengths are equal to or less than the first total opening length. In other words, the total value of the lengths, in the lateral direction, of the second lower electrode openings 22 in each of the cross-sections b1 to b10 is equal to or less than the total value of the lengths, in the lateral direction, of the first lower electrode openings 21 in the cross-section b11.

As illustrated in FIG. 13A-C, the second total opening length tends to increase from the center side toward the end portion side of the pressure chamber 13 in the longitudinal direction. The tendency to increase means that when the second total opening lengths are plotted, a height of a peak (a maximum) increases toward the pressure chamber end portion 7. In other words, a height of a mountain increases from the cross-section b1 toward the cross-section b10. As illustrated, a case where there is a valley (a minimum) in a middle is also included in an increasing tendency. Although the second lower electrode opening 22 is not provided at the cross-sections b2, b4, b6, b8, and b10, such a case also corresponds to the increasing tendency.

Since the second total opening length has such an increasing tendency, the change in stress generated in the piezoelectric body 4 can be gradually reduced toward the pressure chamber end portion 7. Therefore, the change in stress at the pressure chamber end portion 7 can be further reduced.

FIGS. 13B-A and 13B-B are an example different from 13A-A to 13A-C. FIG. 13B-A is a plan schematic view similar to FIG. 13A-B. FIG. 13B-B is a graph plotting the first total opening length and the second total opening lengths in FIG. 13B-A, and is a graph similar to FIG. 13A-C. Also in the example illustrated in FIGS. 13B-A and 13B-B, similarly to the above, the individual second total opening lengths are equal to or less than the first total opening length, and the second total opening length tends to increase from the center side toward the end portion side of the pressure chamber 13 in the longitudinal direction.

In the plot of the second total opening lengths, not only the case where the height of the mountain (a maximum value) increases, but also the case where the height of the valley (a minimum value) increases as illustrated in FIG. 13B-B is included in the case where there is the increasing tendency.

Next, another example of the first lower electrode division 31 and the first lower electrode opening 21 will be described.

In the above examples, at the pressure chamber end portion 7, the lower electrode 3 has the multiple first lower electrode divisions 31 separated from each other, but the present embodiment is not limited thereto. Also at the pressure chamber end portion 9, the lower electrode 3 may have multiple first lower electrode divisions 31 separated from each other. In other words, in the above examples, the first lower electrode opening 21 is provided at the pressure chamber end portion 7, but the present embodiment is not limited thereto, and the first lower electrode opening 21 may be provided at the pressure chamber end portion 9.

FIG. 14 is the plan schematic view for explaining the present example, and is a view similar to FIGS. 3A to 3D.

As illustrated, in the present example, the lower electrode 3 is provided from the inner region to the outer region of the pressure chamber 13 so as to straddle the pressure chamber end portion 7 (one end portion), and the lower electrode 3 is provided from the inner region to the outer region of the pressure chamber 13 so as to straddle the pressure chamber end portion 9 (the other end portion). In other words, the lower electrode 3 straddles both end portions of the pressure chamber 13 in the longitudinal direction.

In this case, the lower electrode 3 preferably includes, at both end portions in the longitudinal direction of the pressure chamber 13, the multiple first lower electrode divisions 31 separated from each other in the lateral direction (the second direction), which is a direction along the end portions. In a case where the lower electrode 3 straddles both end portions in the longitudinal direction of the pressure chamber 13, the lower electrode 3 is divided in the lateral direction at both end portions in the longitudinal direction of the pressure chamber 13, so that the cracks of the piezoelectric body 4 can be prevented at both end portions.

The present example may also be defined using the first lower electrode opening 21. In a case where the lower electrode 3 straddles both end portions in the longitudinal direction of the pressure chamber 13, the first lower electrode opening 21 is provided at both end portions in the longitudinal direction of the pressure chamber 13, so that the piezoelectric body 4 can be prevented from being cracked at both end portions.

Next, an example of the upper electrode opening will be described.

In the present example, the upper electrode 5 has an upper electrode opening that opens from the inner region of the pressure chamber 13 (the opening) to a region outside the pressure chamber 13 through the one end portion along the longitudinal direction (the first direction) when viewed from the laminating direction.

Since the upper electrode 5 has the upper electrode opening, a piezoelectric body region (also referred to as a piezoelectric body drive region) that deforms can be further reduced. As a result, the stress generated in the piezoelectric body 4 corresponding to a periphery of the liquid chamber end portion 7 can be further reduced. Here, the piezoelectric body region (the piezoelectric body drive region) that deforms can be rephrased as a region of the piezoelectric body 4 inside the pressure chamber 13 and in a region where the lower electrode 3 and the upper electrode 5 overlap with each other in the laminating direction. In other words, it corresponds to a region of the piezoelectric body 4 where the stress is generated by the voltage application and causes a deformation.

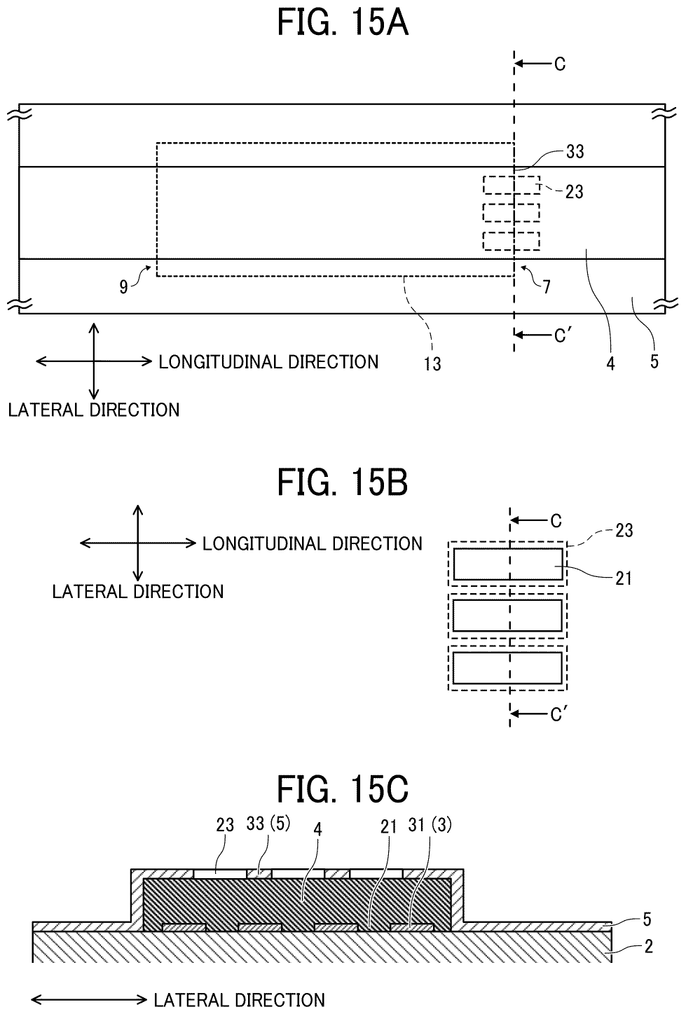

FIGS. 15A to 15C are views illustrating the example of multiple upper electrode openings 23 provided in the upper electrode 5. FIG. 15A is a plan schematic view illustrating the multiple upper electrode openings 23 of the present example. FIG. 15B is a plan schematic view illustrating the multiple upper electrode openings 23 of this example together with the first lower electrode openings 21. FIG. 15C is a cross-sectional schematic view taken along a line CC′ in FIGS. 15A and 15B.

As illustrated in FIG. 15A, the upper electrode opening 23 is opened from the inner region of the pressure chamber 13 (the opening) to the outer region of the pressure chamber 13 through the liquid chamber end portion 7 (the one end portion) along the longitudinal direction. As illustrated in FIG. 15B, the upper electrode opening 23 has a larger area than the first lower electrode opening 21, and is formed to include the first lower electrode opening 21. As illustrated in FIG. 15C, by providing the upper electrode opening 23, a region (the piezoelectric body drive region) of the piezoelectric body 4 sandwiched between the upper electrode 5 and the lower electrode 3 is reduced as compared with, for example, the example illustrated in FIG. 2A.

Since the upper electrode opening 23 does not affect the crystal growth of the piezoelectric body 4, the upper electrode opening 23 can be provided without considering a crystal state of the piezoelectric body 4. Therefore, in order to reduce the stress applied to the piezoelectric body 4, as in the present example, the area of the upper electrode opening 23 is preferably larger than the area of the first lower electrode opening 21.

In the above description, it is defined that the upper electrode 5 has the upper electrode opening 23, but other expressions are also possible. In other words, it can be said that the upper electrode 5 includes multiple upper electrode divisions 33 separated from each other. The upper electrode division 33 is a portion where the upper electrode 5 is present.

In this example, as illustrated in FIG. 15B, the upper electrode opening 23 is formed so as to include a region between the first lower electrode divisions 31 adjacent to each other in the lateral direction (the second direction) when viewed from the laminating direction. In other words, in the present example, the upper electrode opening 23 is formed to include a region where the first lower electrode opening 21 is formed when viewed from the laminating direction.

When viewed from the laminating direction, the electric field is not applied to a region where the upper electrode opening 23 and the first lower electrode opening 21 overlap. Therefore, the electric field is not applied to the piezoelectric body 4 in a portion corresponding to the region where the first lower electrode opening 21 is formed, and the durability can be improved.

Supplements to this example will be described. As described with reference to FIGS. 4A and 4B, when the first lower electrode opening 21 is formed, the randomly oriented piezoelectric body 4b is formed at the location of the first lower electrode opening 21. In this example, since the upper electrode opening 23 is formed to include the region where the first lower electrode opening 21 is formed, it is ensured that the electric field is not applied to the randomly oriented piezoelectric body 4b. Therefore, a portion where the electric field is applied to the randomly oriented piezoelectric body 4b can be reduced, and the durability of the piezoelectric body 4 is improved.

As illustrated in FIG. 15B, in this example, the area of the upper electrode opening 23 is larger than the area of the first lower electrode opening 21. The case where the area of the upper electrode opening 23 is the same as the area of the first lower electrode opening 21, in other words, the case where the upper electrode opening 23 and the first lower electrode opening 21 have the same planar shape also corresponds to the case where the upper electrode opening 23 is formed to include the region where the first lower electrode opening 21 is formed.

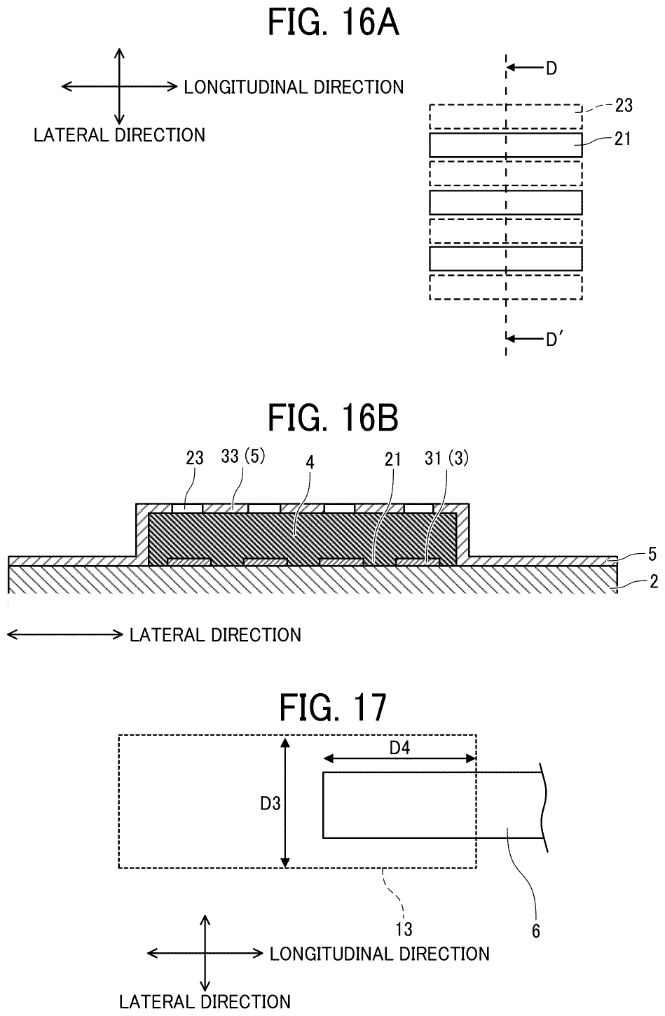

The shape, number, arrangement, and the like of the upper electrode openings 23 can be appropriately changed. Another example of the upper electrode opening 23 will be described with reference to FIGS. 16A and 16B. FIG. 16A is a plan schematic view illustrating the upper electrode openings 23 of this example together with the first lower electrode openings 21, and is a plan schematic view similar to FIG. 15B. FIG. 16B is a cross-sectional schematic view taken along the line DD′ of FIG. 16A.

In the present example, the multiple first lower electrode openings 21 is provided, and the upper electrode opening 23 is formed in a region of the first lower electrode division 31 when viewed from the laminating direction. In other words, in the present example, the multiple first lower electrode openings 21 is provided, and the upper electrode opening 23 is formed in a region between the first lower electrode openings 21 when viewed from the laminating direction.

As illustrated in FIG. 16B, the region where the lower electrode 3 and the upper electrode 5 overlap with each other is reduced in the laminating direction, the stress of the piezoelectric body 4 can be reduced at the pressure chamber end portion 7, and the durability can be improved. In this example, a distance between the electrodes (a distance between the lower electrode 3 and the upper electrode 5) in the laminating direction can be extended to lower an electric field strength. As a result, the stress applied to the piezoelectric body 4 can be reduced, and durability can be improved.

As described in FIGS. 9B-A to 9B-C, the planar shape of the upper electrode opening 23 is preferably a round shape. When the planar shape of the upper electrode opening 23 is a round shape, it is possible to alleviate the stress fluctuation generated at the opening end portion of the upper electrode opening 23.

The piezoelectric actuator of the present embodiment includes the extraction electrode 6. The extraction electrode 6 may be referred to as an extended wire or the like. The extraction electrode 6 is formed on the upper electrode 5 and is electrically connected to the upper electrode 5. For example, an insulating film may be formed on the upper electrode 5, a contact hole may be formed in the insulating film, and the extraction electrode 6 and the upper electrode 5 may be connected via the contact hole.

The thickness of the extraction electrode 6 is preferably larger than the thickness of the upper electrode 5. In this case, resistance of the extraction electrode 6 can be reduced, and power consumption can be reduced.

As illustrated in FIG. 1, for example, the extraction electrode 6 is preferably provided from the inner region to the outer region of the pressure chamber 13 (the opening) so as to straddle the pressure chamber end portion 7 (the one end portion). Since the extraction electrode 6 is formed across the pressure chamber end portion 7, the rigidity of the laminated film at the pressure chamber end portion 7 can be improved, and failure due to stress can be reduced.

The planar shape of the extraction electrode 6 can be appropriately changed. FIG. 17 illustrates an example. FIG. 17 is a plan schematic view for describing the present example.

In the present example, when viewed from the laminating direction, the length of the pressure chamber 13 in the lateral direction (the second direction) at the central portion of the pressure chamber 13 (the opening) in the longitudinal direction (the first direction) is defined as the opening width D3, and the length, in the longitudinal direction, of the extraction electrode 6 inside the pressure chamber 13 is defined as an extended electrode length D4. In this example, the extended electrode length D4 is twice or less the opening width D3.

In a mathematical expression, this can be expressed as D4≤2D3.

The pressure chamber has a width D3 in the second direction, the extraction electrode has an inner part disposed corresponding to an inner region of the pressure chamber, the inner region of the extraction electrode has a length D4 in the first direction, and the length D4 is twice or less of the width D3.

In a case where the thickness of the extraction electrode 6 is larger than the thickness of the upper electrode 5, if the region that restrains the inside of the pressure chamber 13 is too wide, the displacement may be reduced, and discharge characteristics may be deteriorated. Therefore, it is preferable that the size of the extraction electrode 6 does not exceed a certain size. As a result of intensive studies, it is preferable that the extended electrode length D4, which is the length in the longitudinal direction of the extraction electrode 6 formed inside the pressure chamber 13 when viewed from the laminating direction, is twice or less the opening width D3. In this case, it is possible to simultaneously satisfy prevention of the failure and securing of the displacement amount.

Next, an example of a method for manufacturing the piezoelectric actuator and the liquid discharge head according to the present embodiment will be described.

(a) As the actuator substrate 100, for example, a silicon single crystal substrate (for example, a plate thickness of 400 μm) having a plane orientation (110) is used, and the diaphragm 2 is formed on this substrate.

The diaphragm 2 can have a structure in which a silicon oxide film and a silicon nitride film are laminated by, for example, a low pressure-chemical vapor deposition (LP-CVD) method or the like.

A material of the diaphragm 2 may be other materials, and for example, other materials such as silicon and zircon oxide may be used, or other elements may be implanted for stress control. Alternatively, an active layer or the like of a silicon-on-insulator (SOI) wafer may be used or formed.

In addition, the silicon plane orientation of the substrate is not limited to (110), and a silicon plane orientation suitable for flowing in a subsequent process may be selected.

The material and thickness of the diaphragm 2 can be appropriately selected according to performance required for the piezoelectric actuator and the liquid discharge head.

The material of the diaphragm 2 is preferably, for example, a material having a Young's modulus of 50 GPa or more and 180 GPa or less. The thickness of the diaphragm 2 is preferably, for example, 1 μm or more and 5 μm or less.

The rigidity of the diaphragm 2 can be increased by increasing the Young's modulus of the material of the diaphragm 2 and increasing the thickness of the diaphragm 2, but it is necessary to increase the applied voltage in order to deform the piezoelectric element. On the other hand, by reducing the Young's modulus of the material of the diaphragm 2 and reducing the thickness of the diaphragm 2, the diaphragm 2 is easily deformed, and the applied voltage for deforming the piezoelectric element can be reduced, but the rigidity of the diaphragm 2 is reduced and the diaphragm 2 is easily damaged.

Thus, by setting the Young's modulus and the thickness of the diaphragm 2 within the above ranges, it is possible to keep the voltage for driving the piezoelectric element within an appropriate range while maintaining the rigidity of the diaphragm 2.

(b) Next, film formation is performed for the lower electrode 3 and then patterning is performed to form the lower electrode 3 of the piezoelectric element. During patterning, the first lower electrode opening 21 is also formed. During this patterning, the second lower electrode opening 22 can also be formed. In this example, for example, Pt is used as the material of the lower electrode 3.

Next, as the piezoelectric body 4, PZT is deposited in multiple times, for example, by spin coating, and finally, a film having a thickness of 2 μm is formed.

Next, the upper electrode 5 made of strontium ruthenate (SRO) and Pt is deposited in a thickness of 40 nm and 100 nm, respectively, by, for example, a sputtering method.

The method for forming the film of the piezoelectric body 4 is not limited to a sol-gel method using spin coating, and the film may be formed by, for example, the sputtering method, an ion plating method, an air sol method, an inkjet method, or the like.

The lower electrode 3 and the upper electrode 5 may be made of Pt, Ir, In, Ti, Au, Cu, or the like. Compounds such as oxides and nitrides having conductivity can also be used.

As such a material, the above-described strontium ruthenate (SRO), TiN, IrO₂, indium tin oxide (ITO), ZnO, SnO₂, or the like may be used. In addition, a single-layer film or a laminated film of these materials may be used. As in the above-described example, SRO may be laminated on Pt, and as another example, Ir may be laminated on Pt.

Here, as an example, a method in a case where the piezoelectric body 4 is formed by the sol-gel method will be described.

A PZT precursor is laminated on Pt as the lower electrode 3 and fired. At this time, the firing is performed, for example, in three steps of drying (120° C.), calcining (380° C.), and firing (700° C.).

As a result, this makes it possible to obtain good crystallinity with PZT (100) as the piezoelectric body 4 on the lower electrode 3.

On the other hand, the crystal orientation of the piezoelectric body 4 formed directly on the diaphragm 2 randomly grows as compared with the piezoelectric body 4 formed on the lower electrode 3. The randomly oriented piezoelectric body contains many defects, and it is difficult to take a dense crystal form. Therefore, when an external force is applied, a minute crack is likely to occur, which may become a starting point of failure. For this reason, in the present embodiment, the piezoelectric element is formed by sequentially laminating the lower electrode, the piezoelectric body, and the upper electrode on the diaphragm. However, at the first lower electrode opening 21, the piezoelectric body 4 is formed on the diaphragm 2 (see FIGS. 4A, 4B, and the like).

Although lead zirconate titanate (PZT) is used as the material of the piezoelectric body 4, any dopant may be added to PZT. Examples of the dopant include Nb, Mn, and Ce. The composition of lead, titanium, and zirconium of PZT may be appropriately adjusted according to desired piezoelectricity or a production method. A ratio of titanium to zirconium may be 52:48, which is a composition of a morphotropic phase boundary, or may be adjusted in a range of 42:58 to 62:38 according to desired characteristics and a production method.

Next, regions of the piezoelectric body 4 and the upper electrode 5 are adjusted by a litho-etch method so as to be positioned corresponding to the pressure chamber 13 to be formed later, thereby forming the piezoelectric body 4 and the upper electrode 5.

(c) Next, as the extraction electrode 6, for example, TiN and Al are formed to have film thicknesses of 30 nm and 3 μm, respectively, by the sputtering method.

Pt, which is a material of the lower electrode 3 or the upper electrode 5, is in direct contact with Al, which is a material of the extraction electrode 6, at a connection portion with the upper electrode 5 or a connection portion with the lower electrode 3, whereby the Pt is alloyed by a heat history in a later step. TiN is applied as a barrier layer for preventing alloying in order to prevent film peeling and the like from occurring due to stress caused by a volume change resulted from the alloying.

The material of the extraction electrode 6 can be appropriately selected. It is sufficient to use a material having low resistance, and for example, the extraction electrode 6 may be formed of a material containing Au, Ni, Cr, or the like.

In this example, the lower electrode 3 is an individual electrode, and the upper electrode 5 is a common electrode. However, functions thereof may be reversed.

(d) Next, the support substrate 200 in which the gap 18 is formed at a position corresponding to the piezoelectric element is manufactured by, for example, a litho-etch method. For example, Si processing is performed by a dry etching method.

Next, the support substrate 200 and the actuator substrate 100 are bonded by, for example, an adhesive.

The adhesive is applied to the support substrate 200 side with a thickness of about 1 μm by a general thin film transfer device.

Next, in order to form the pressure chamber 13, the actuator substrate 100 is polished by a known technique so as to have a desired thickness t (for example, a thickness of 80 μm). The actuator substrate 100 may be etched instead of being polished.

(e) Next, the actuator substrate 100 is coated with a resist by a lithography method. Next, anisotropic wet etching is performed with an alkaline solution (KOH solution or TMHA solution) to form the pressure chamber 13. The pressure chamber 13 may be formed by the dry etching using an inductively coupled plasma (ICP) etcher, for example, in addition to the anisotropic etching using an alkaline solution.

(f) Next, the nozzle substrate 300 is separately formed, in which the nozzles 8 are opened at positions corresponding to the respective pressure chambers 13, and the nozzle substrate 300 is bonded to the actuator substrate 100.

As a result, the liquid discharge head 10 of the present example is manufactured.

Next, a method for evaluating the above-described durability of the piezoelectric actuator according to the present embodiment will be described. The durability is evaluated by applying a voltage between the lower electrode 3 and the upper electrode 5 constituting the piezoelectric element 11. Regarding the voltage application, a durability test is performed in which a voltage waveform that is a rectangular wave is repeatedly applied to the piezoelectric element 11. Then, the durability is determined by evaluating a state of the piezoelectric element after the durability test. Conditions of the voltage waveform are a rectangular wave having a voltage amplitude of 40 V, a frequency of 120 kHz, and a duty of 50%, and the number of times of application is 10¹¹. After the voltage waveform is applied, the piezoelectric element 11 is observed with an optical microscope to confirm presence or absence of damage, and it is confirmed whether capacitance of the piezoelectric element 11 is within an allowable range (for example, a variation of 10% or less) to determine the presence or absence of damage. Damage of the piezoelectric element 11 due to cracks or the like can be confirmed by observation with a microscope, and disconnection of the upper electrode 5 and the lower electrode 3 due to damage can be confirmed by a change in capacitance.

The method for evaluating the durability is not limited to this evaluation. For example, an excessive voltage may be applied to the piezoelectric element, and an upper limit voltage at which the piezoelectric element is not damaged may be used as an index of durability. Alternatively, the above-described durability evaluation may be applied after an acceleration test by temperature or humidity is performed.

### Liquid Discharge Apparatus

The liquid discharge apparatus according to the present embodiment will be described.

The liquid discharge apparatus according to the present embodiment includes the liquid discharge head according to the present embodiment and a driver that drives the piezoelectric element of the piezoelectric actuator according to the present embodiment.

The liquid discharge apparatus of the present embodiment can be, for example, an image forming apparatus, a printing apparatus, a recording apparatus, an inkjet recording apparatus, an inkjet printer, or the like.

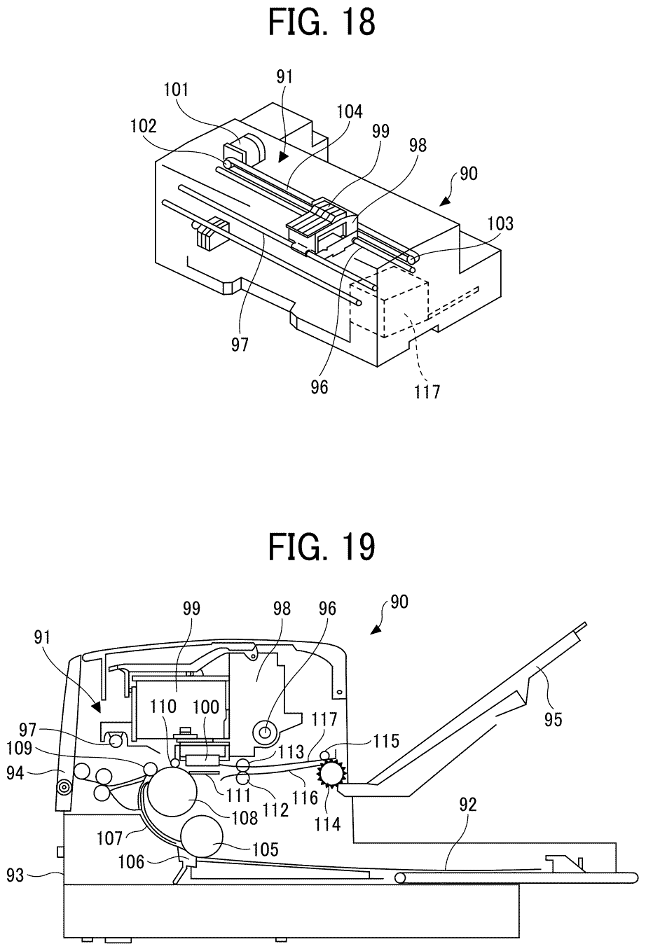

FIGS. 18 and 19 illustrate an example of the liquid discharge apparatus according to the present embodiment. FIG. 18 is a perspective schematic view of an inkjet recording apparatus 90 that is an example of a liquid discharge apparatus. FIG. 19 is a side schematic view of the apparatus. FIG. 19 may be a cross-sectional schematic view of the apparatus.

The inkjet recording apparatus 90 includes, for example, a carriage 98, the liquid discharge head 10 mounted on the carriage 98, an ink cartridge 99, and the like. The carriage 98 is movable in an apparatus main body in a scanning direction. The ink cartridge 99 supplies ink to the liquid discharge head 10. A portion including the carriage 98, the ink cartridge 99, and the like is referred to as a printing mechanism portion 91.

A sheet feeding cassette 93 is detachably attached to a lower portion of the apparatus main body. The sheet feeding cassette 93 can load a large number of sheets 92 from a front side. The sheet feeding cassette 93 may be a sheet feeding tray. In addition, the inkjet recording apparatus 90 includes a bypass feeder 94 openable to manually feed the sheet 92.

The inkjet recording apparatus 90 takes in the sheet 92 fed from the sheet feeding cassette 93 or the bypass feeder 94, and records a required image by the printing mechanism portion 91. Thereafter, the sheet 92 on which the image is recorded is ejected to a sheet ejection tray 95. The sheet ejection tray 95 is mounted on, for example, a rear face side of the apparatus.

The printing mechanism portion 91 includes a main guide rod 96 and a sub-guide rod 97. The main guide rod 96 and the sub-guide rod 97 are guide members laterally bridged on left and right side plates. The printing mechanism portion 91 holds the main guide rod 96 and the sub-guide rod 97 so that the carriage 98 can slidably move in a main scanning direction.

The liquid discharge head 10 discharges ink droplets of respective colors of yellow (Y), cyan (C), magenta (M), and black (Bk), for example. The liquid discharged by the liquid discharge head 10 is not limited thereto, and can be appropriately changed. Furthermore, one liquid discharge head that discharges ink of each color may be used.

The liquid discharge head 10 includes multiple nozzles. The liquid discharge head 10 is mounted on the carriage 98 such that, for example, an arrangement direction of the nozzles is a direction intersecting the main scanning direction. The liquid discharge head 10 is mounted on the carriage 98 such that a discharge direction is downward.

Each ink cartridge 99 for supplying ink of each color to the liquid discharge head 10 is mounted on the carriage 98. The ink cartridge 99 is replaceable. An atmosphere port is provided above the ink cartridge 99, and a supply port is provided below the ink cartridge 99. The atmosphere port communicates with the atmosphere. The ink is supplied from the supply port to the liquid discharge head 10. A porous body filled with ink is provided inside the supply port. The ink supplied to the liquid discharge head 10 is maintained at a slight negative pressure by the capillary force of the porous body.

The carriage 98 is slidably fitted on the main guide rod 96 on the rear side (downstream side in a sheet conveyance direction) and slidably mounted on the sub-guide rod 97 on the front side (upstream side in the sheet conveyance direction). In order for the carriage 98 to move and scan in the main scanning direction, a timing belt 104 is stretched between a driving pulley 102 and a driven pulley 103. The carriage 98 is secured to the timing belt 104. The driving pulley 102 and the driven pulley 103 are rotationally driven by a main scanning motor 101. The carriage 98 is reciprocated by forward and reverse rotation of the main scanning motor 101.

The inkjet recording apparatus 90 includes a sheet feeding roller 105, a friction pad 106, a guide member 107, a conveyance roller 108, a conveyance roll 109, and a leading end portion roll 110. The inkjet recording apparatus 90 uses these to convey the sheet 92 set in the sheet feeding cassette 93 to a lower side of the liquid discharge head 10.

The sheet feeding roller 105 and the friction pad 106 separate and feed the sheet 92 from the sheet feeding cassette 93. The guide member 107 guides the sheet 92. The conveyance roller 108 reverses and conveys the fed sheet 92. The conveyance roller 108 is driven to rotate via a gear train by a sub-scanning motor. The conveyance roll 109 is pressed against a peripheral surface of the conveyance roller 108. The leading end portion roll 110 defines a feeding angle of the sheet 92 from the conveyance roller 108.

The inkjet recording apparatus 90 includes a print receiving member 111 which is a sheet guide member. The print receiving member 111 guides, on the lower side of the liquid discharge head 10, the sheet 92 fed from the conveyance roller 108 in accordance with a movement range of the carriage 98 in the main scanning direction.

A conveyance roll 112 and a spur 113 are provided on a downstream side of the print receiving member 111 in a sheet conveyance direction. The conveyance roll 112 and the spur 113 perform rotational driving for feeding the sheet 92 in a sheet ejection direction.

The inkjet recording apparatus 90 is provided with a sheet ejection roller 114, a spur 115, and guide members 116 and 117. The sheet ejection roller 114 and the spur 115 feed out the sheet 92 to the sheet ejection tray 95. The guide members 116 and 117 form a sheet ejection path.

The inkjet recording apparatus 90 drives the liquid discharge head 10 according to an image signal while moving the carriage 98 during recording. As a result, the ink is discharged onto the stopped sheet 92 to record one row, and then the sheet 92 is conveyed by a predetermined amount to perform recording of next row. When the inkjet recording apparatus 90 receives a signal indicating that a rear end of the sheet 92 has reached a recording area or an end of recording operation, the inkjet recording apparatus 90 terminates a recording operation and ejects the sheet 92.

The inkjet recording apparatus 90 includes, for example, a recovery device 117 at a position deviated from the recording area on a right end side in a moving direction of the carriage 98. The recovery device 117 recovers discharge failure of the liquid discharge head 10. The recovery device 117 includes, for example, a capping unit, a suction unit, and a cleaning unit. An example of a recovery operation by the recovery device 117 will be described.

The inkjet recording apparatus 90 moves the carriage 98 to the recovery device 117 during printing standby, and caps the liquid discharge head 10 with a capping unit. As a result, the nozzles of the liquid discharge head 10 can be kept wet, and the discharge failure due to ink drying can be suppressed.

By using the recovery device 117, the inkjet recording apparatus 90 can also discharge ink irrelevant to recording during recording or the like. As a result, ink viscosity can be made constant between the nozzles, and a stable discharge state can be maintained.

In a case where the discharge failure occurs, for example, an operation of sealing a discharge face (which may be referred to as a nozzle forming face or the like) of the liquid discharge head 10 may be performed by the capping unit. The discharge face is sealed by the capping unit, and for example, the ink, bubbles in the ink, and the like are sucked from the nozzle by the suction unit through the tube. As a result, the discharge failure can be recovered. The sucked ink is, for example, discharged to a waste ink reservoir installed in a lower part of the apparatus main body, and absorbed and held by an ink absorber inside the waste ink reservoir.

Ink, dust, and the like adhering to the nozzle forming face of the liquid discharge head 10 may be removed by the cleaning unit. As a result, the discharge failure can be recovered.

Since the inkjet recording apparatus 90 is equipped with the liquid discharge head 10 of the present embodiment, it has good durability and reliability, stable discharge characteristics are obtained, and image quality is improved.

The lower electrode includes a lower electrode opening between each of the multiple lower electrode divisions adjacent to each other, and the lower electrode opening has a rounded part in a plan shape.

The upper electrode opening has a rounded part in a plan shape.

A liquid discharge head includes: the piezoelectric actuator; and a nozzle plate bonded to one face of the substrate opposite to another face of the substrate bonded to the diaphragm, the nozzle plate having a nozzle communicating with the pressure chamber, wherein the pressure chamber stores a liquid to be discharged from the nozzle.

In the above description, the case where the liquid discharge head 10 discharges ink has been mainly described as an example, but the liquid discharged by the liquid discharge head 10 is not limited to the ink. Examples of the liquid other than the ink include a liquid resist for patterning.

According to the present embodiment, it is possible to provide a piezoelectric actuator with improved durability of a piezoelectric element.

Aspects of the present embodiment are, for example, as follows.

According to a first aspect (Aspect 1),
a piezoelectric actuator includes:
a substrate having an opening;
a diaphragm formed on one face of the substrate and formed in a region including the opening; and
a piezoelectric element in which a lower electrode, a piezoelectric body, and an upper electrode are sequentially laminated on the diaphragm on an opposite side to the substrate,
in which the piezoelectric element has a portion extending from an inner region to an outer region of the opening when viewed from a laminating direction of the piezoelectric element, a direction in this portion from the inner region to the outer region of the opening being defined as a first direction, and
the lower electrode includes multiple first lower electrode divisions separated from each other in a second direction that is a direction along at least one end portion of the opening in the first direction when viewed from the laminating direction.

According to a second aspect (Aspect 2),
in the piezoelectric actuator of the first aspect (Aspect 1),
when a length of the lower electrode in the second direction at the one end portion is defined as a first lower electrode width D1 and a length of the lower electrode in the second direction at a central portion of the opening in the first direction is defined as a second lower electrode width D2 when viewed from the laminating direction,

D1≥D2
is satisfied.

According to a third aspect (Aspect 3),
in the piezoelectric actuator of the first aspect (Aspect 1) or the second aspect (Aspect 2),
when the length of the lower electrode in the second direction at the central portion of the opening in the first direction is defined as the second lower electrode width D2 and a length of the opening in the second direction at the central portion of the opening in the first direction is defined as an opening width D3 when viewed from the laminating direction,

D2<D3
is satisfied.

According to a fourth aspect (Aspect 4),
in the piezoelectric actuator according to any one of the first aspect (Aspect 1) to the third aspect (Aspect 3),
the lower electrode includes at least three or more of the first lower electrode divisions, and multiple second lower electrode divisions that is formed in the inner region of the opening when viewed from the laminating direction, is separated from each other in the second direction, and is provided to be separated from the first lower electrode divisions in the first direction, and
each of the second lower electrode divisions is disposed so as to overlap with a region between the corresponding two adjacent first lower electrode divisions in the first direction.

According to a fifth aspect (Aspect 5),
in the piezoelectric actuator according to any one of the first aspect (Aspect 1) to the fourth aspect (Aspect 4),
a distance L between two of the first lower electrode divisions adjacent to each other in the second direction and a thickness x of the piezoelectric body satisfy:

L≤1.4x.

According to a sixth aspect (Aspect 6),
in the piezoelectric actuator of the second aspect (Aspect 2),
a total length of the multiple first lower electrode divisions in the second direction is shorter than the second lower electrode width D2.

According to a seventh aspect (Aspect 7),
in the piezoelectric actuator according to any one of the first aspect (Aspect 1) to the sixth aspect (Aspect 6),
the lower electrode includes the second lower electrode divisions formed in the inner region of the opening when viewed from the laminating direction,
the multiple second lower electrode divisions is provided in the second direction, is separated from each other in the second direction, and is separated from the first lower electrode divisions in the first direction, and
a total length of the multiple second lower electrode divisions in the second direction is longer than the total length of the multiple first lower electrode divisions in the second direction.

According to an eighth aspect (Aspect 8),
in the piezoelectric actuator of the seventh aspect (Aspect 7),
the total length of the second lower electrode divisions in the second direction decreases from a center side toward an end portion side of the opening in the first direction, and the total length of the second lower electrode divisions in the second direction is equal to or less than the total length of the first lower electrode divisions in the second direction.

According to a ninth aspect (Aspect 9),
in the piezoelectric actuator according to any one of the first aspect (Aspect 1) to the eighth aspect (Aspect 8),
the lower electrode includes first lower electrode openings disposed between the multiple first lower electrode divisions adjacent to each other, and second lower electrode openings disposed on the center side of the opening in the first direction with respect to the first lower electrode openings,
the multiple first lower electrode openings and the multiple second lower electrode openings are provided, and
when a total length of the multiple first lower electrode openings in a cross-section in the second direction is defined as a first total opening length, and a total length of the multiple second lower electrode openings in the cross-section in the second direction is defined as a second total opening length,
the second total opening length is equal to or less than the first total opening length, and has a tendency to increase from the center side toward the end portion side of the opening in the first direction.

According to a tenth aspect (Aspect 10),
the piezoelectric actuator according to any one of the first aspect (Aspect 1) to the ninth aspect (Aspect 9) includes an extended electrode that is formed on the upper electrode, electrically connected to the upper electrode, and has a thickness larger than a thickness of the upper electrode,
in which the extended electrode is provided from the inner region to the outer region of the opening so as to straddle the one end portion.

According to an eleventh aspect (Aspect 11),
in the piezoelectric actuator of the tenth aspect (Aspect 10),
when the length of the opening in the second direction at the central portion of the opening in the first direction when viewed from the laminating direction is defined as the opening width D3, and a length of the extended electrode formed inside the opening in the first direction is defined as an extended electrode length D4,
the extended electrode length D4 is twice or less the opening width D3.

According to a twelfth aspect (Aspect 12),
in the piezoelectric actuator according to any one of the first aspect (Aspect 1) to the eleventh aspect (Aspect 11),
the upper electrode includes an upper electrode opening that opens along the first direction from the inner region of the opening to the outer region of the opening through the one end portion when viewed from the laminating direction.

According to a thirteenth aspect (Aspect 13),
in the piezoelectric actuator of the twelfth aspect (Aspect 12),
the upper electrode opening is formed to include a region between the first lower electrode divisions adjacent to each other in the second direction when viewed from the laminating direction.

According to a fourteenth aspect (Aspect 14),
in the piezoelectric actuator of the twelfth aspect (Aspect 12),
the upper electrode opening is formed in a region of the first lower electrode division when viewed from the laminating direction.

According to a fifteenth aspect (Aspect 15),
in the piezoelectric actuator according to any one of the first aspect (Aspect 1) to the fourteenth aspect (Aspect 14),
the lower electrode includes a first lower electrode opening disposed between the multiple first lower electrode divisions adjacent to each other, and
a planar shape of the first lower electrode opening is a round shape.

According to a sixteenth aspect (Aspect 16), in the piezoelectric actuator of the twelfth aspect (Aspect 12),
a planar shape of the upper electrode opening is a round shape.

According to a seventeenth aspect (Aspect 17),
a liquid discharge head includes:
the piezoelectric actuator according to any one of the first aspect (Aspect 1) to the sixteenth aspect (Aspect 16); and
a nozzle member that is bonded to the substrate on an opposite side to the diaphragm of the substrate to form a nozzle corresponding to the opening,
in which a liquid stored in the opening is discharged from the nozzle.

According to an eighteenth aspect (Aspect 18),
a liquid discharge apparatus includes:
the liquid discharge head of the seventeenth aspect (Aspect 17); and
a driver that drives the piezoelectric element of the piezoelectric actuator.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. A piezoelectric actuator comprising:
a substrate having a pressure chamber elongated in a first direction, the pressure chamber having one end in the first direction;
a diaphragm on the substrate and having a one face facing the pressure chamber; and
a piezoelectric element including:
a lower electrode;
a piezoelectric body; and
an upper electrode,
sequentially laminated on another face of the diaphragm opposite to the one face,
the piezoelectric element extending across the one end of the pressure chamber in the first direction, and
the lower electrode including multiple lower electrode divisions across the one end in the first direction and separated from each other in a second direction orthogonal to the first direction.

2. The piezoelectric actuator according to claim 1,
wherein an expression:
D1≥D2
is satisfied,
where a first lower electrode width D1 is a length of the lower electrode in the second direction at the one end of the pressure chamber; and
a second lower electrode width D2 is a length of the lower electrode in the second direction at a center of the pressure chamber in the first direction.

3. The piezoelectric actuator according to claim 1,
wherein an expression:
D2<D3
is satisfied,
where a second lower electrode width D2 is a length of the lower electrode in the second direction at a center of the pressure chamber in the first direction; and
a pressure chamber width D3 is a length of the pressure chamber in the second direction at the center of the pressure chamber in the first direction.

4. The piezoelectric actuator according to claim 1,
wherein the lower electrode includes:
the multiple lower electrode divisions disposed across the one end of the pressure chamber in the first direction, the multiple lower electrode divisions including two or more lower electrodes; and
another multiple lower electrode divisions disposed inside the pressure chamber in the first direction,
wherein said another multiple lower electrode divisions are:
separated from each other in the second direction; and
separated from the multiple lower electrode divisions in the first direction, and
one of said another multiple lower electrode divisions is disposed between two of the multiple lower electrode divisions adjacent to each other.

5. The piezoelectric actuator according to claim 1,
herein an expression:
L≤1.4x
is satisfied,
where L is a distance between two of the multiple lower electrode divisions adjacent to each other in the second direction; and
x is a thickness x of the piezoelectric body.

6. The piezoelectric actuator according to claim 2,
wherein a total length of the multiple lower electrode divisions in the second direction is shorter than the second lower electrode width D2.

7. The piezoelectric actuator according to claim 1,
wherein the lower electrode includes another multiple lower electrode divisions inside the pressure chamber in the first direction,
said another multiple lower electrode divisions are:
separated from each other in the second direction, and
separated from the multiple lower electrode divisions in the first direction, and
a total length of said another multiple lower electrode divisions in the second direction is longer than a total length of the multiple lower electrode divisions in the second direction.

8. The piezoelectric actuator according to claim 7,
wherein the total length of said another multiple lower electrode divisions in the second direction decreases from a center of the pressure chamber toward the one end of the pressure chamber in the first direction, and
the total length of said another multiple lower electrode divisions in the second direction is equal to or larger than the total length of the multiple lower electrode divisions in the second direction.

9. The piezoelectric actuator according to claim 7,
wherein the multiple lower electrode divisions include first multiple openings separated in the second direction to define the multiple lower electrode divisions,
said another multiple lower electrode divisions include second multiple openings separated in the second direction to define said another multiple lower electrode divisions,
a total length of the second multiple openings in the second direction is equal to or less of a total length of the first multiple openings in the second direction, and
the total length of the second multiple openings increases from a center of the pressure chamber toward the one end of the pressure chamber in the first direction.

10. The piezoelectric actuator according to claim 1 comprising an extraction electrode on the upper electrode, the extraction electrode:
electrically connected to the upper electrode;
having a thickness larger than a thickness of the upper electrode; and
extending across the one end of the pressure chamber in the first direction.

11. The piezoelectric actuator according to claim 10,
wherein the pressure chamber has a width D3 in the second direction,
the extraction electrode has an inner part disposed corresponding to an inner region of the pressure chamber,
the inner region of the extraction electrode has a length D4 in the first direction, and
the length D4 is twice or less of the width D3.

12. The piezoelectric actuator according to claim 1,
wherein the upper electrode includes multiple upper electrode openings each extending across the one end of the pressure chamber in the first direction.

13. The piezoelectric actuator according to claim 12,
wherein the multiple upper electrode openings covers a region between one of the multiple lower electrode divisions and another of the multiple lower electrode divisions adjacent to the one of the multiple lower electrode divisions in the second direction.

14. The piezoelectric actuator according to claim 12,
wherein the multiple upper electrode openings respectively cover the multiple lower electrode divisions in a plane of the diaphragm.

15. The piezoelectric actuator according to claim 1,
wherein the lower electrode includes a lower electrode opening between each of the multiple lower electrode divisions adjacent to each other, and
the lower electrode opening has a rounded part in a plan shape.

16. The piezoelectric actuator according to claim 12,
wherein the upper electrode opening has a rounded part in a plan shape.

17. A liquid discharge head comprising:
the piezoelectric actuator according to claim 1; and
a nozzle plate bonded to one face of the substrate opposite to another face of the substrate bonded to the diaphragm, the nozzle plate having a nozzle communicating with the pressure chamber,
wherein the pressure chamber stores a liquid to be discharged from the nozzle.

18. A liquid discharge apparatus comprising:
the liquid discharge head according to claim 17; and
a driver to drive a piezoelectric element of a piezoelectric actuator.
